(19) United States
(12) Patent Application Publication
(10) Pub. No.: US 2020/0342926 A1
(43) Pub. Date: Oct. 29, 2020

(54) ONE SELECTOR ONE RESISTOR MRAM CROSSPOINT MEMORY ARRAY FABRICATION METHODS

(71) Applicant: SanDisk Technologies LLC, Addison, TX (US)

(72) Inventors: Jordan A. Katine, Mountain View, CA (US); Mac D. Apodaca, San Jose, CA (US); Christopher J. Petti, Mountain View, CA (US)

(73) Assignee: SanDisk Technologies LLC, Addison, TX (US)

(21) Appl. No.: 16/396,710

(22) Filed: Apr. 28, 2019

(51) Int. Cl. G11C 11/16; H01L 43/12; H01L 27/22; H01L 43/10; H01L 43/08; H01L 43/02

(52) U.S. Cl. CPC G11C 11/161; H01L 43/12; H01L 27/224; H01L 43/10; G11C 11/1657; H01L 43/02; G11C 11/1675; G11C 11/1673; G11C 11/1655; H01L 43/08

(57) ABSTRACT

A memory array is provided that includes a first memory level including a plane of first selector material, and a plurality of first memory cells each including a corresponding first magnetic memory element coupled in series with a corresponding first selector element. Each first selector element includes a region of the plane of first selector material.

### BACKGROUND

Memory is widely used in various electronic devices such as cellular telephones, digital cameras, personal digital assistants, medical electronics, mobile computing devices, non-mobile computing devices and data servers. Memory may be non-volatile memory or volatile memory. A non-volatile memory allows information to be stored and retained even when the non-volatile memory is not connected to a source of power (e.g., a battery).

One example of a non-volatile memory is magnetoresistive random access memory (MRAM), which uses magnetization to represent stored data, in contrast to some other memory technologies that store data using electronic charge. Generally, MRAM includes a large number of magnetic memory cells formed on a semiconductor substrate, where each memory cell represents one bit of data. A bit of data is written to a memory cell by changing the direction of magnetization of a magnetic element within the memory cell, and a bit is read by measuring the resistance of the memory cell (low resistance typically represents a “0” bit, and high resistance typically represents a “1” bit). As used herein, direction of magnetization is the direction of orientation of the magnetic moment.

Although MRAM is a promising technology, numerous design and process challenges remain.

### BRIEF DESCRIPTION OF THE DRAWINGS

FIGS. 1A-1H depict various embodiments of a memory system.

FIG. 2A depicts an embodiment of a portion of a three-dimensional memory array.

FIG. 2B depicts an embodiment of a memory cell of the three-dimensional memory array of FIG. 2A.

FIG. 2C depicts an example current-voltage characteristic of a threshold selector device of FIG. 2B.

FIGS. 3A-3B depict an embodiment of a cross-point memory array.

FIGS. 4A-4B depict various views of an embodiment of a cross-point memory array.

FIGS. 5A1-5H3 are cross-sectional views of a portion of a substrate during an example fabrication of the memory array of FIGS. 4A-4B.

FIGS. 6A-6B depict various views of another embodiment of a cross-point memory array.

FIGS. 7A1-7J3 are cross-sectional views of a portion of a substrate during an example fabrication of the memory array of FIGS. 6A-6B.

FIGS. 8A-8B depict various views of still another embodiment of a cross-point memory array.

FIGS. 8C-8D depict various views of yet another embodiment of a cross-point memory array.

### DETAILED DESCRIPTION

Memory arrays and methods of forming memory arrays are provided. In particular, cross-point memory arrays and methods of forming cross-point memory arrays are provided. In an embodiment, a cross-point memory array (and methods of forming such a cross-point memory array) are provided that include a plurality of memory cells, each memory cell comprising a magnetic memory element and a selector element, each selector element disposed above or below a corresponding magnetic memory element. In another embodiment, a cross-point memory array (and methods of forming such a cross-point memory array) are provided that include a plurality of memory cells, each memory cell comprising a magnetic memory element and a selector element, each selector element comprising a region of a row of selector element material. In another embodiment, a cross-point memory array (and methods of forming such a cross-point memory array) are provided that include a plurality of memory cells, each memory cell comprising a magnetic memory element, and a selector element, each selector element comprising a region of a plane of selector element material.

In an embodiment, memory cells within a memory array may include re-writable non-volatile memory cells including a reversible resistance-switching element. A reversible resistance-switching element may include a reversible resistivity-switching material having a resistivity that may be reversibly switched between two or more states. In an embodiment, the reversible resistance-switching material may include a metal oxide, solid electrolyte, phase-change material, magnetic material, or other similar resistivity-switching material. Various metal oxides can be used, such as transition metal-oxides. Examples of metal-oxides include, but are not limited to, NiO, Nb₂O₅, TiO₂, HfO₂, Al₂O₃, MgOₓ, CrO₂, VO, BN, TaO₂, Ta₂O₃, and AlN.

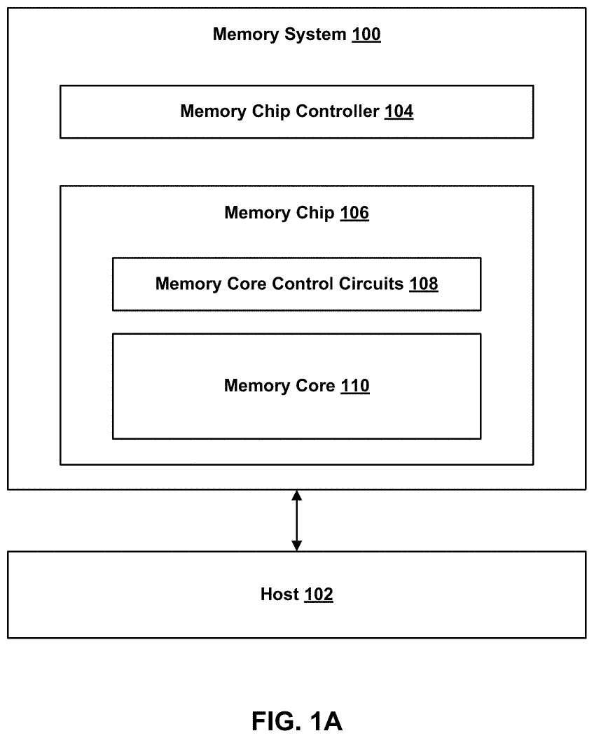

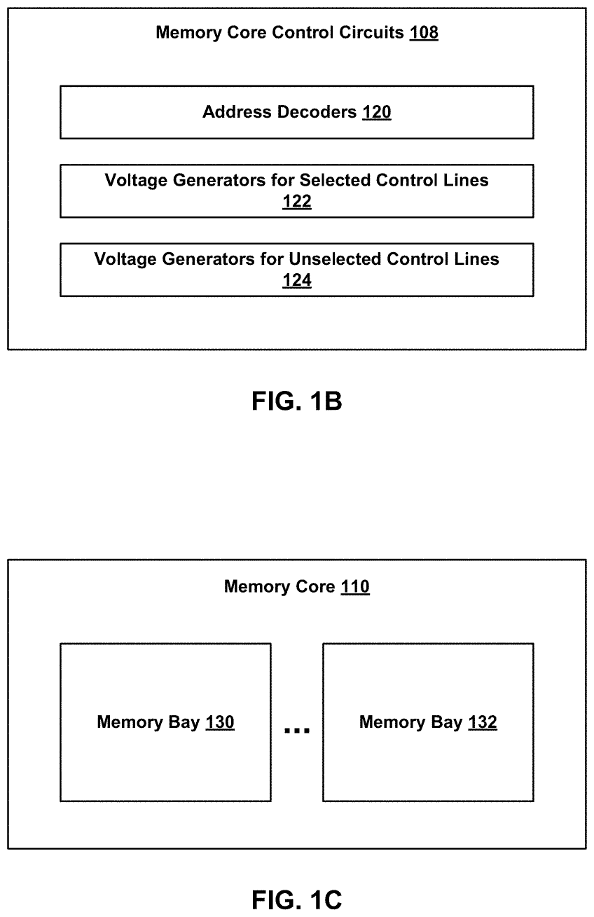

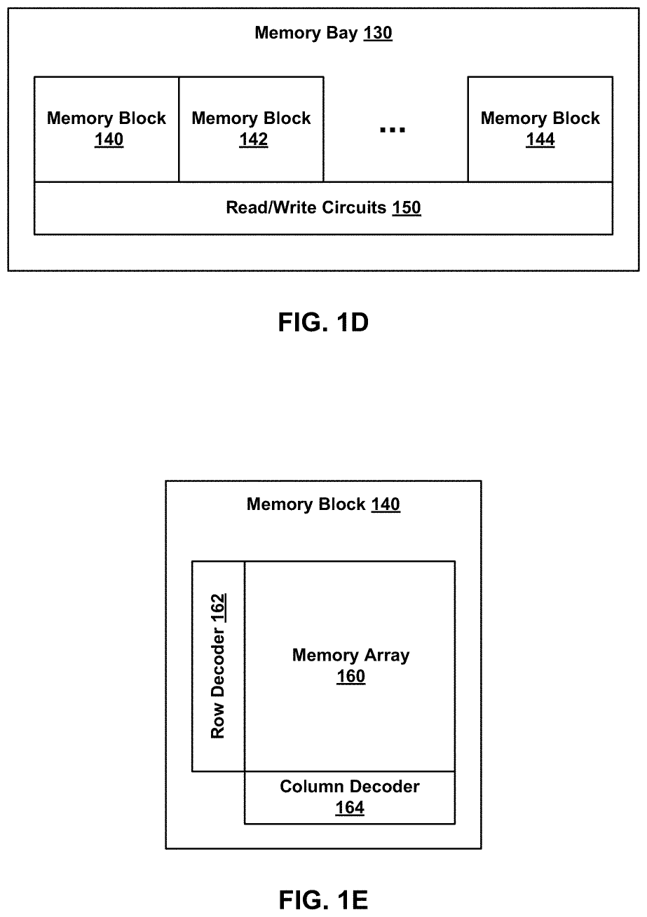

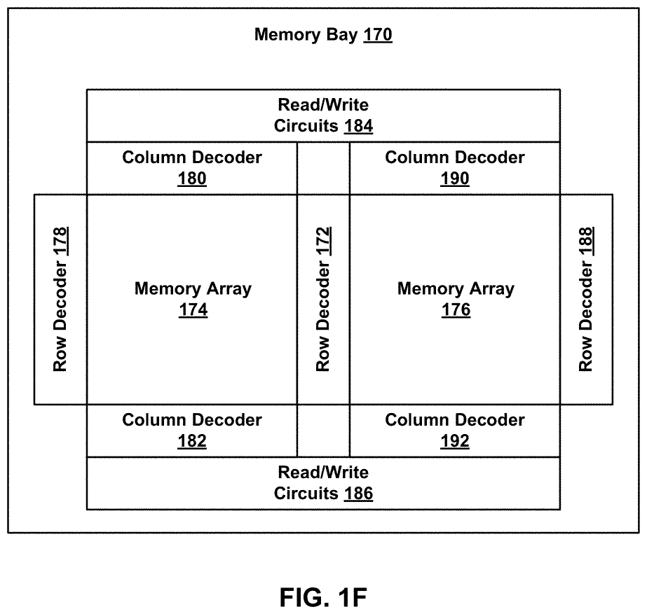

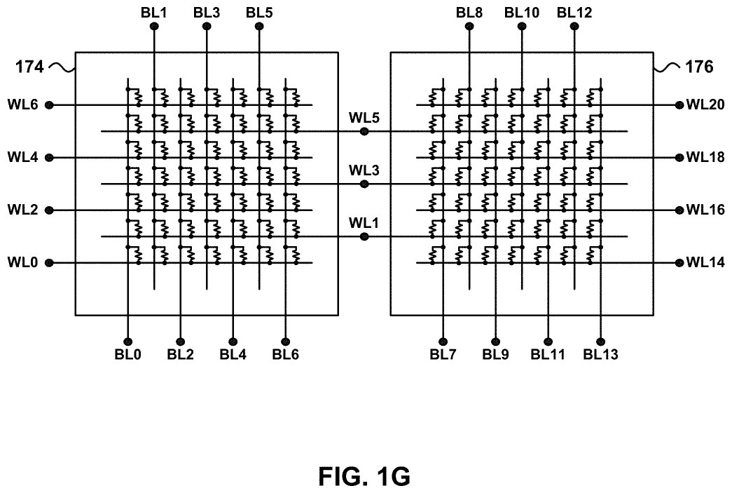

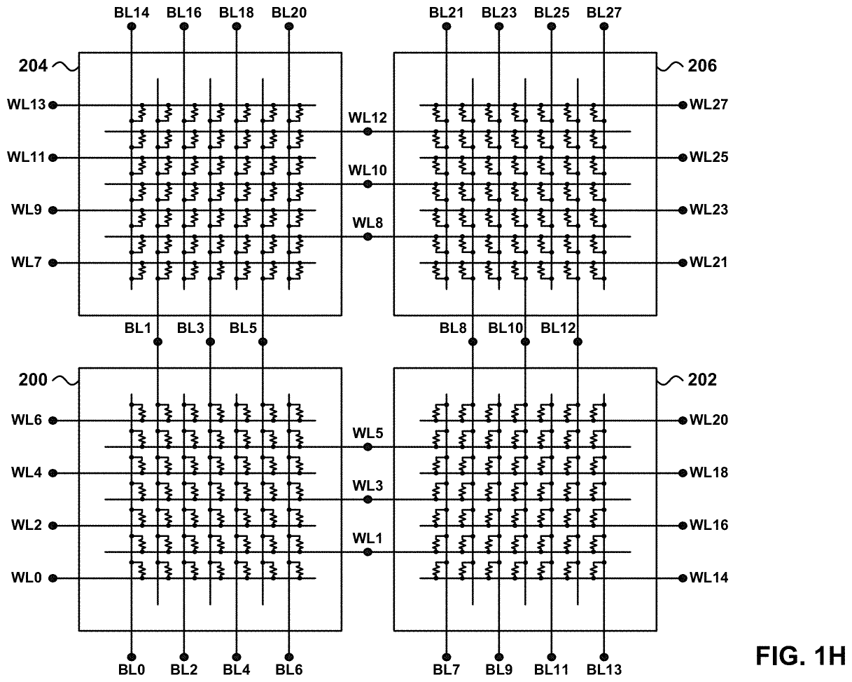

FIG. 1A depicts one embodiment of a memory system 100 and a host 102. Memory system 100 may include a non-volatile storage system interfacing with host 102 (e.g., a mobile computing device or a server). In some cases, memory system 100 may be embedded within host 102. As examples, memory system 100 may be a memory card, a solid-state drive (SSD) such a high density MLC SSD (e.g., 2-bits/cell or 3-bits/cell) or a high performance SLC SSD, or a hybrid HDD/SSD drive.

As depicted, memory system 100 includes a memory chip controller 104 and a memory chip 106. Memory chip 106 may include volatile memory and/or non-volatile memory. Although a single memory chip is depicted, memory system 100 may include more than one memory chip. Memory chip controller 104 may receive data and commands from host 102 and provide memory chip data to host 102.

Memory chip controller 104 may include one or more state machines, page registers, SRAM, and control circuitry for controlling the operation of memory chip 106. The one or more state machines, page registers, SRAM, and control circuitry for controlling the operation of the memory chip may be referred to as managing or control circuits. The managing or control circuits may facilitate one or more memory array operations including forming, erasing, programming, or reading operations.

In some embodiments, the managing or control circuits (or a portion of the managing or control circuits) for facilitating one or more memory array operations may be integrated within memory chip 106. Memory chip controller 104 and memory chip 106 may be arranged on a single integrated circuit or arranged on a single die. In other embodiments, memory chip controller 104 and memory chip 106 may be arranged on different integrated circuits. In some cases, memory chip controller 104 and memory chip 106 may be integrated on a system board, logic board, or a PCB.

Memory chip 106 includes memory core control circuits 108 and a memory core 110. Memory core control circuits 108 may include logic for controlling the selection of memory blocks (or arrays) within memory core 110, controlling the generation of voltage references for biasing a particular memory array into a read or write state, and generating row and column addresses.

Memory core 110 may include one or more two-dimensional arrays of memory cells and/or one or more three-dimensional arrays of memory cells. In an embodiment, memory core control circuits 108 and memory core 110 may be arranged on a single integrated circuit. In other embodiments, memory core control circuits 108 (or a portion of memory core control circuits 108) and memory core 110 may be arranged on different integrated circuits.

A memory operation may be initiated when host 102 sends instructions to memory chip controller 104 indicating that host 102 would like to read data from memory system 100 or write data to memory system 100. In the event of a write (or programming) operation, host 102 may send to memory chip controller 104 both a write command and the data to be written. Memory chip controller 104 may buffer data to be written and may generate error correction code (ECC) data corresponding with the data to be written. The ECC data, which allows data errors that occur during transmission or storage to be detected and/or corrected, may be written to memory core 110 or stored in non-volatile memory within memory chip controller 104. In an embodiment, the ECC data are generated and data errors are corrected by circuitry within memory chip controller 104.

Memory chip controller 104 may control operation of memory chip 106. In an example, before issuing a write operation to memory chip 106, memory chip controller 104 may check a status register to make sure that memory chip 106 is able to accept the data to be written. In another example, before issuing a read operation to memory chip 106, memory chip controller 104 may pre-read overhead information associated with the data to be read. The overhead information may include ECC data associated with the data to be read or a redirection pointer to a new memory location within memory chip 106 in which to read the data requested.

Once memory chip controller 104 initiates a read or write operation, memory core control circuits 108 may generate appropriate bias voltages for word lines and bit lines within memory core 110, as well as generate the appropriate memory block, row, and column addresses.

In some embodiments, one or more managing or control circuits may be used for controlling the operation of a memory array within memory core 110. The one or more managing or control circuits may provide control signals to a memory array to perform a read operation and/or a write operation on the memory array. In one example, the one or more managing or control circuits may include any one of or a combination of control circuitry, state machines, decoders, sense amplifiers, read/write circuits, and/or controllers.

The one or more managing circuits may perform or facilitate one or more memory array operations including erasing, programming, or reading operations. In one example, one or more managing circuits may include an on-chip memory controller for determining row and column address, word line and bit line addresses, memory array enable signals, and data latching signals.

FIG. 1B depicts one embodiment of memory core control circuits 108. As depicted, memory core control circuits 108 include address decoders 120, voltage generators for selected control lines 122, and voltage generators for unselected control lines 124. Control lines may include word lines, bit lines, or a combination of word lines and bit lines. Selected control lines may include selected word lines or selected bit lines that are used to place memory cells into a selected state. Unselected control lines may include unselected word lines or unselected bit lines that are used to place memory cells into an unselected state.

Voltage generators (or voltage regulators) for selected control lines 122 may include one or more voltage generators for generating selected control line voltages. Voltage generators for unselected control lines 124 may include one or more voltage generators for generating unselected control line voltages. Address decoders 120 may generate memory block addresses, as well as row addresses and column addresses for a particular memory block.

FIGS. 1C-1F depict one embodiment of a memory core organization that includes a memory core 110 having multiple memory bays, and each memory bay having multiple memory blocks. Although a memory core organization is disclosed where memory bays include memory blocks, and memory blocks include a group of memory cells, other organizations or groupings also can be used with the technology described herein.

FIG. 1C depicts an embodiment of memory core 110 of FIG. 1A. As depicted, memory core 110 includes memory bay 130 and memory bay 132. In some embodiments, the number of memory bays per memory core can be different for different implementations. For example, a memory core may include only a single memory bay or multiple memory bays (e.g., 16 memory bays, 256 memory bays, etc.).

FIG. 1D depicts one embodiment of memory bay 130 of FIG. 1C. As depicted, memory bay 130 includes memory blocks 140-144 and read/write circuits 150. In some embodiments, the number of memory blocks per memory bay may be different for different implementations. For example, a memory bay may include one or more memory blocks (e.g., 32 memory blocks per memory bay).

Read/write circuits 150 include circuitry for reading and writing memory cells within memory blocks 140-144. As depicted, read/write circuits 150 may be shared across multiple memory blocks within a memory bay. This allows chip area to be reduced because a single group of read/write circuits 150 may be used to support multiple memory blocks. However, in some embodiments, only a single memory block may be electrically coupled to read/write circuits 150 at a particular time to avoid signal conflicts.

In some embodiments, read/write circuits 150 may be used to write one or more pages of data into memory blocks 140-144 (or into a subset of the memory blocks). The memory cells within memory blocks 140-144 may permit direct over-writing of pages (i.e., data representing a page or a portion of a page may be written into memory blocks 140-144 without requiring an erase or reset operation to be performed on the memory cells prior to writing the data).

In an example, memory system 100 of FIG. 1A may receive a write command including a target address and a set of data to be written to the target address. Memory system 100 may perform a read-before-write (RBW) operation to read the data currently stored at the target address before performing a write operation to write the set of data to the target address. Memory system 100 may then determine whether a particular memory cell may stay at its current state (i.e., the memory cell is already at the correct state), needs to be set to a “0” state, or needs to be reset to a “1” state.

Memory system 100 may then write a first subset of the memory cells to the “0” state and then write a second subset of the memory cells to the “1” state. The memory cells that are already at the correct state may be skipped over, thereby improving programming speed and reducing the cumulative voltage stress applied to unselected memory cells.

A particular memory cell may be set to the “1” state by applying a first voltage difference across the particular memory cell of a first polarity (e.g., +1.5V). The particular memory cell may be reset to the “0” state by applying a second voltage difference across the particular memory cell of a second polarity that is opposite to that of the first polarity (e.g., −1.5V).

In some cases, read/write circuits 150 may be used to program a particular memory cell to be in one of three or more data/resistance states (i.e., the particular memory cell may comprise a multi-level memory cell). In an example, read/write circuits 150 may apply a first voltage difference (e.g., 2V) across the particular memory cell to program the particular memory cell to a first state of the three or more data/resistance states, or a second voltage difference (e.g., 1V) across the particular memory cell that is less than the first voltage difference to program the particular memory cell to a second state of the three or more data/resistance states.

Applying a smaller voltage difference across the particular memory cell may cause the particular memory cell to be partially programmed or programmed at a slower rate than when applying a larger voltage difference. In another example, read/write circuits 150 may apply a first voltage difference across the particular memory cell for a first time period (e.g., 150 ns) to program the particular memory cell to a first state of the three or more data/resistance states, or apply the first voltage difference across the particular memory cell for a second time period less than the first time period (e.g., 50 ns). One or more programming pulses followed by a memory cell verification phase may be used to program the particular memory cell to be in the correct state.

FIG. 1E depicts one embodiment of memory block 140 of FIG. 1D. As depicted, memory block 140 includes a memory array 160, a row decoder 162, and a column decoder 164. Memory array 160 may include a contiguous group of memory cells having contiguous word lines and bit lines. Memory array 160 may include one or more layers of memory cells, and may include a two-dimensional memory array and/or a three-dimensional memory array.

Row decoder 162 decodes a row address and selects a particular word line in memory array 160 when appropriate (e.g., when reading or writing memory cells in memory array 160). Column decoder 164 decodes a column address and selects a particular group of bit lines in memory array 160 to be electrically coupled to read/write circuits, such as read/write circuits 150 of FIG. 1D. In an embodiment, the number of word lines is 4K per memory layer, the number of bit lines is 1K per memory layer, and the number of memory layers is 4, providing a memory array 160 containing 16M memory cells. Other numbers of word lines per layer, bit lines per layer, and number of layers may be used.

FIG. 1F depicts an embodiment of a memory bay 170. Memory bay 170 is an example of an alternative implementation for memory bay 130 of FIG. 1D. In some embodiments, row decoders, column decoders, and read/write circuits may be split or shared between memory arrays. As depicted, row decoder 172 is shared between memory arrays 174 and 176, because row decoder 172 controls word lines in both memory arrays 174 and 176 (i.e., the word lines driven by row decoder 172 are shared).

Row decoders 178 and 172 may be split such that even word lines in memory array 174 are driven by row decoder 178 and odd word lines in memory array 174 are driven by row decoder 172. Column decoders 180 and 182 may be split such that even bit lines in memory array 174 are controlled by column decoder 182 and odd bit lines in memory array 174 are driven by column decoder 180. The selected bit lines controlled by column decoder 180 may be electrically coupled to read/write circuits 184. The selected bit lines controlled by column decoder 182 may be electrically coupled to read/write circuits 186. Splitting the read/write circuits into read/write circuits 184 and 186 when the column decoders are split may allow for a more efficient layout of the memory bay.

Row decoders 188 and 172 may be split such that even word lines in memory array 176 are driven by row decoder 188 and odd word lines in memory array 176 are driven by row decoder 172. Column decoders 190 and 192 may be split such that even bit lines in memory array 176 are controlled by column decoder 192 and odd bit lines in memory array 176 are driven by column decoder 190. The selected bit lines controlled by column decoder 190 may be electrically coupled to read/write circuits 184. The selected bit lines controlled by column decoder 192 may be electrically coupled to read/write circuits 186. Splitting the read/write circuits into read/write circuits 184 and 186 when the column decoders are split may allow for a more efficient layout of the memory bay.

FIG. 1G depicts an embodiment of a schematic diagram (including word lines and bit lines) corresponding with memory bay 170 in FIG. 1F. As depicted, word lines WL1, WL3, and WL5 are shared between memory arrays 174 and 176 and controlled by row decoder 172 of FIG. 1F. Word lines WL0, WL2, WL4, and WL6 are driven from the left side of memory array 174 and controlled by row decoder 178 of FIG. 1F. Word lines WL14, WL16, WL18, and WL20 are driven from the right side of memory array 176 and controlled by row decoder 188 of FIG. 1F.

Bit lines BL0, BL2, BL4, and BL6 are driven from the bottom of memory array 174 and controlled by column decoder 182 of FIG. 1F. Bit lines BL1, BL3, and BL5 are driven from the top of memory array 174 and controlled by column decoder 180 of FIG. 1F. Bit lines BL7, BL9, BL11, and BL13 are driven from the bottom of memory array 176 and controlled by column decoder 192 of FIG. 1F. Bit lines BL8, BL10, and BL12 are driven from the top of memory array 176 and controlled by column decoder 190 of FIG. 1F.

In an embodiment, memory arrays 174 and 176 may include memory layers that are oriented in a plane that is horizontal to the supporting substrate. In another embodiment, memory arrays 174 and 176 may include memory layers that are oriented in a plane that is vertical with respect to the supporting substrate (i.e., the vertical plane is substantially perpendicular to the supporting substrate). In this case, the bit lines of the memory arrays may include substantially vertical bit lines.

FIG. 1H depicts one embodiment of a schematic diagram (including word lines and bit lines) corresponding with a memory bay arrangement wherein word lines and bit lines are shared across memory blocks, and both row decoders and column decoders are split. Sharing word lines and/or bit lines helps to reduce layout area because a single row decoder and/or column decoder can be used to support two memory arrays.

As depicted, word lines WL1, WL3, and WL5 are shared between memory arrays 200 and 202. Bit lines BL1, BL3, and BL5 are shared between memory arrays 200 and 204. Word lines WL8, WL10, and WL12 are shared between memory arrays 204 and 206. Bit lines BL8, BL10, and BL12 are shared between memory arrays 202 and 206.

Row decoders are split such that word lines WL0, WL2, WL4, and WL6 are driven from the left side of memory array 200 and word lines WL1, WL3, and WL5 are driven from the right side of memory array 200. Likewise, word lines WL7, WL9, WL11, and WL13 are driven from the left side of memory array 204 and word lines WL8, WL10, and WL12 are driven from the right side of memory array 204.

Column decoders are split such that bit lines BL0, BL2, BL4, and BL6 are driven from the bottom of memory array 200 and bit lines BL1, BL3, and BL5 are driven from the top of memory array 200. Likewise, bit lines BL7, BL9, BL11, and BL13 are driven from the bottom of memory array 202 and bit lines BL8, BL10, and BL12 are driven from the top of memory array 202. Splitting row and/or column decoders also helps to relieve layout constraints (e.g., the column decoder pitch can be relieved by 2× since the split column decoders need only drive every other bit line instead of every bit line).

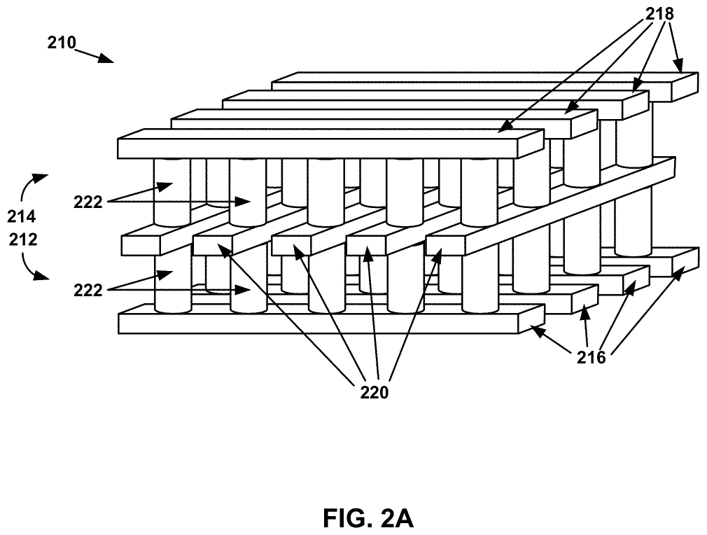

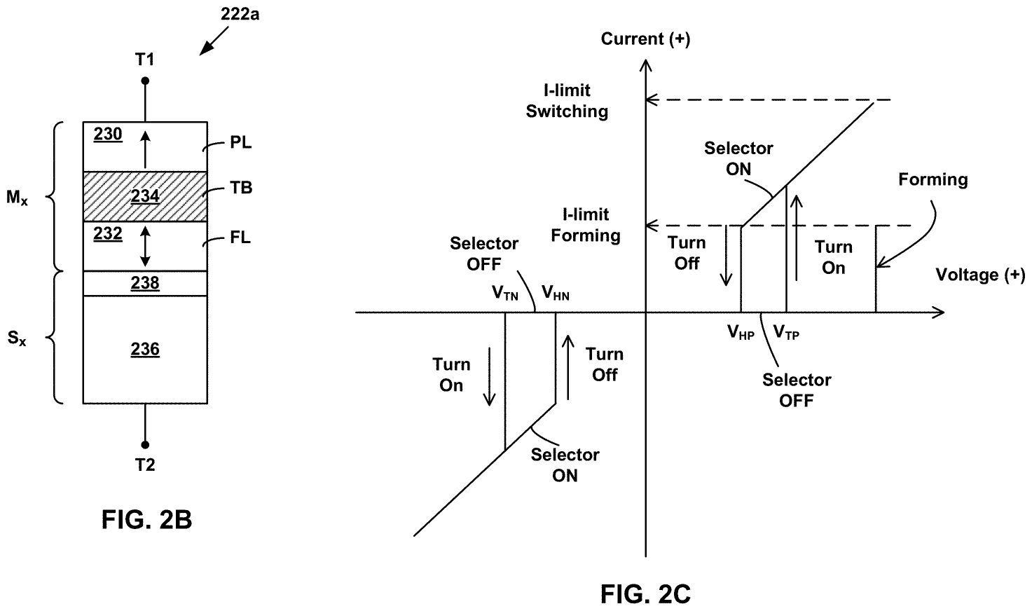

FIG. 2A depicts an embodiment of a portion of a monolithic three-dimensional memory array 210 that includes a first memory level 212, and a second memory level 214 positioned above first memory level 212. Memory array 210 is an example of an implementation of memory array 160 in FIG. 1E. Word lines 216 and 218 are arranged in a first direction and bit lines 220 are arranged in a second direction perpendicular to the first direction. As depicted, the upper conductors of first memory level 212 may be used as the lower conductors of second memory level 214. In a memory array with additional layers of memory cells, there would be corresponding additional layers of bit lines and word lines.

Memory array 210 includes a plurality of memory cells 222, each of which may include re-writeable memory cells. In an embodiment, each of memory cells 222 are vertically-oriented. Memory cells 222 may include non-volatile memory cells or volatile memory cells. With respect to first memory level 212, a first portion of memory cells 222 are between and connect to word lines 216 and bit lines 220. With respect to second memory level 214, a second portion of memory cells 222 are between and connect to word lines 218 and bit lines 220.

In an embodiment, each memory cell 222 includes a selector element coupled in series with a magnetic memory element, where each memory cell 222 represents one bit of data. FIG. 2B is a simplified schematic diagram of a memory cell 222a, which is one example implementation of memory cells 222 of FIG. 2A. In an embodiment, memory cell 222a includes a magnetic memory element Mₓ coupled in series with a selector element Sₓ, both coupled between a first terminal T1 and a second terminal T2. In an embodiment, memory cell 222a is vertically-oriented. In the embodiment of FIG. 2B, magnetic memory element Mₓ is disposed above selector element Sₓ. In other embodiments, selector element Sₓ may be disposed above magnetic memory element Mₓ.

In an embodiment, magnetic memory element Mₓ is a magnetic tunnel junction, and selector element Sₓ is a threshold selector device. In an embodiment, selector element Sₓ is a conductive bridge threshold selector device. In other embodiments, selector element Sₓ is an ovonic threshold switch (e.g., binary SiTe, CTe, BTe, AlTe, etc., or the ternary type AsTeSi, AsTeGe or AsTeGeSiN, etc.), a Metal Insulator Transition (MIT) of a Phase Transition Material type (e.g., VO₂, NbO₂ etc.), or other similar threshold selector device.

In an embodiment, magnetic memory element Mₓ includes an upper ferromagnetic layer 230, a lower ferromagnetic layer 232, and a tunnel barrier (TB) 234 which is an insulating layer between the two ferromagnetic layers. In this example, lower ferromagnetic layer 232 is a free layer (FL) that has a direction of magnetization that can be switched. Upper ferromagnetic layer 230 is the pinned (or fixed) layer (PL) that has a direction of magnetization that is not easily changed. In other embodiments, magnetic memory element Mₓ may include fewer, additional, or different layers than those depicted in FIG. 2B. In other embodiments, lower ferromagnetic layer 232 is a pinned layer (PL) and upper ferromagnetic layer 230 is the free layer (FL).

When the direction of magnetization in free layer 232 is parallel to that of pinned layer 230, the resistance RP (referred to herein as “parallel resistance RP”) across magnetic memory element Mₓ is relatively low. When the direction of magnetization in free layer 232 is anti-parallel to that of pinned layer 230, the resistance RAP (referred to herein as “anti-parallel resistance RAP”) across magnetic memory element Mₓ is relatively high. The data state (“0” or “1”) of magnetic memory element Mₓ is read by measuring the resistance of magnetic memory element Mₓ. By design, both the parallel and anti-parallel configurations remain stable in the quiescent state and/or during a read operation (at sufficiently low read current).

In an embodiment, selector element Sₓ is an ovonic threshold switch that includes a first region 236 and optionally includes a second region 238 disposed above first region 236. In an embodiment, first region 236 is a SiTe alloy, and optional second region 238 is carbon nitride. Other materials may be used for first region 236 and optional second region 238. In other embodiments, selector element Sₓ is a conductive bridge threshold selector element. In an embodiment, first region 236 is a solid electrolyte region, and second region 238 is an ion source region.

FIG. 2C is a diagram depicting example current-voltage (I-V) characteristics of a threshold selector device Sₓ. Each threshold selector device Sₓ is initially in a high resistance (OFF) state. To operate threshold selector device Sₓ as a threshold switch, an initial forming step may be necessary so that threshold selector device Sₓ operates in a current range in which switching can occur. Following forming, threshold selector device Sₓ may be switched ON and OFF, and may be used as either a unipolar or a bipolar threshold selector device. Accordingly, threshold selector device Sₓ may be referred to as a bipolar threshold selector device.

In the example I-V characteristics of FIG. 2C, for positive applied voltages, threshold selector device Sₓ remains in a high resistance state (HRS) (e.g., OFF) until the voltage across the device meets or exceeds (i.e., is more positive than) a first threshold voltage, V_{TP}, at which point threshold selector device Sₓ switches to a low resistance state (LRS) (e.g., ON). Threshold selector device Sₓ remains turned ON until the voltage across the device drops to or below a first hold voltage, V_{HP}, at which point threshold selector device 224 turns OFF.

For negative applied voltages, threshold selector device Sₓ remains in a HRS (e.g., OFF) until the voltage across the device meets or exceeds (i.e., is more negative than) a second threshold voltage, V_{TN}, at which point threshold selector device 304 switches to a LRS (e.g., ON). Threshold selector device Sₓ remains turned ON until the voltage across the device increases to or exceeds (i.e., is less negative than) a second hold voltage, V_{HN}, at which point threshold selector device Sₓ turns OFF.

Referring again to FIG. 2B, in an embodiment, magnetic memory element Mₓ uses spin-transfer-torque (STT) switching. To “set” a bit value of magnetic memory element Mₓ (i.e., choose the direction of the free layer magnetization), an electrical write current is applied from first terminal T1 to second terminal T2. The electrons in the write current become spin-polarized as they pass through pinned layer 230 because pinned layer 230 is a ferromagnetic metal.

A substantial majority of the conduction electrons in a ferromagnet will have a spin orientation that is parallel to the direction of magnetization, yielding a net spin polarized current. (Electron spin refers to angular momentum, which is directly proportional to but anti-parallel in direction to the magnetic moment of the electron, but this directional distinction will not be used going forward for ease of discussion.)

When the spin-polarized electrons tunnel across TB 234, conservation of angular momentum can result in the imparting of a torque on both free layer 232 and pinned layer 230, but this torque is inadequate (by design) to affect the direction of magnetization of pinned layer 230. Contrastingly, this torque is (by design) sufficient to switch the direction of magnetization of free layer 232 to become parallel to that of pinned layer 230 if the initial direction of magnetization of free layer 232 was anti-parallel to pinned layer 230. The parallel magnetizations will then remain stable before and after such write current is turned OFF.

In contrast, if free layer 232 and pinned layer 230 magnetizations are initially parallel, the direction of magnetization of free layer 232 can be STT-switched to become anti-parallel to that of pinned layer 230 by applying a write current of opposite direction to the aforementioned case. Thus, by way of the same STT physics, the direction of the magnetization of free-layer 232 can be deterministically set into either of two stable orientations by judicious choice of the write current direction (polarity).

In the example described above, spin-transfer-torque (STT) switching is used to “set” a bit value of magnetic memory element Mₓ. In other embodiments, field-induced switching, spin orbit torque (SOT) switching, VCMA (magnetoelectric) switching, or other switching techniques may be employed.

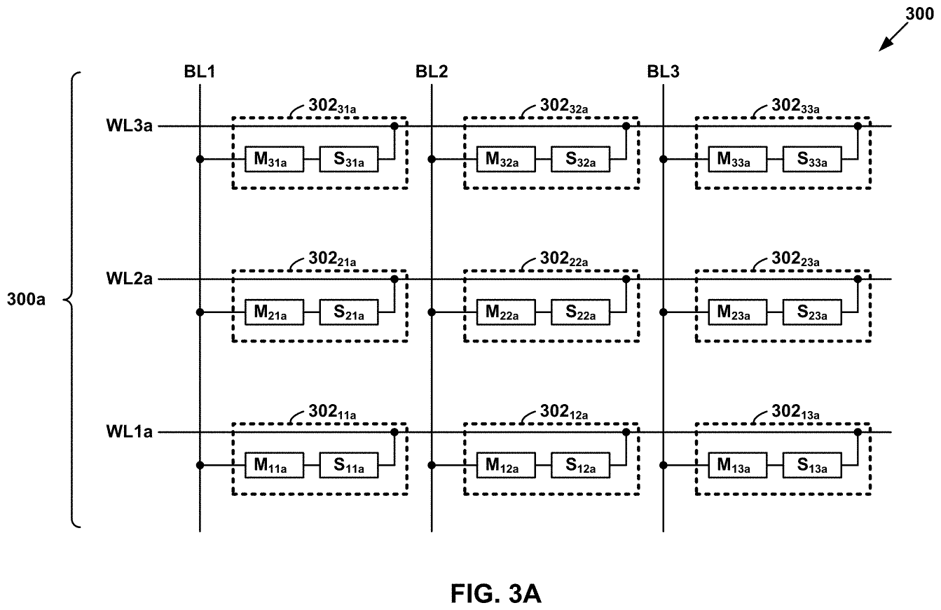

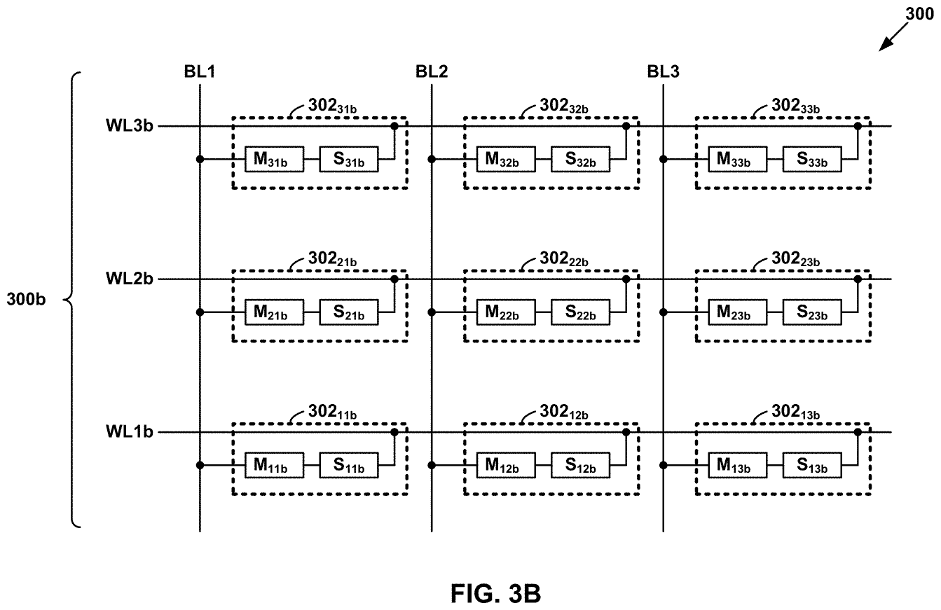

FIGS. 3A-3B are simplified schematic diagrams of an example cross-point memory array 300 which includes a first memory level 300a, and a second memory level 300b positioned above first memory level 300a. Cross-point memory array 300 is an example of an implementation of memory array 160 in FIG. 1E. Cross-point memory array 300 may include more than two memory levels.

Cross-point memory array 300 includes word lines WL1a, WL2a, WL3a, WL1b, WL2b, and WL3b, and bit lines BL1, BL2, and BL3. First memory level 300a includes memory cells 302₁₁ₐ, 302₁₂ₐ, . . . , 302₃₃ₐ coupled to word lines WL1a, WL2a, WL3a and bit lines BL1, BL2, and BL3, and second memory level 300b includes memory cells 302_{11b}, 302_{12b}, . . . , 302_{33b} coupled to word lines WL1b, WL2b, WL3b and bit lines BL1, BL2, and BL3. In an embodiment, each of memory cells 302₁₁ₐ, 302₁₂ₐ, . . . , 302₃₃ₐ are vertically-oriented. In an embodiment, each of memory cells 302_{11b}, 302_{12b}, . . . , 302_{33b} are vertically-oriented.

First memory level 300a is one example of an implementation for first memory level 212 of monolithic three-dimensional memory array 210 of FIG. 2B, and second memory level 300b is one example of an implementation for second memory level 214 of monolithic three-dimensional memory array 210 of FIG. 2B. In an embodiment, each of memory cells 302₁₁ₐ, 302₁₂ₐ, . . . , 302₃₃ₐ, 302_{11b}, 302_{12b}, . . . , 302_{33b}, is an implementation of memory cell 222a of FIG. 2B. Persons of ordinary skill in the art will understand that cross-point memory array 300 may include more or less than six word lines, more or less than three bit lines, and more or less than eighteen memory cells 302₁₁ₐ, 302₁₂ₐ, . . . , 302₃₃ₐ, 302_{11b}, 302_{12b}, . . . , 302_{33b}. In some embodiments, cross-point memory array 300 may include 1000×1000 memory cells, although other array sizes may be used.

Each memory cell 302₁₁ₐ, 302₁₂ₐ, . . . , 302₃₃ₐ, 302_{11b}, 302_{12b}, . . . , 302_{33b} is coupled to one of the word lines and one of the bit lines, and includes a corresponding magnetic memory element M₁₁ₐ, M₁₂ₐ, . . . , M₃₃ₐ, M_{11b}, M_{12b}, . . . , M_{33b}, respectively, coupled in series with a corresponding selector element S₁₁ₐ, S₁₂, . . . , S₃₃ₐ, S_{11b}, S_{12b}, . . . , S_{33b}, respectively. In an embodiment, each of magnetic memory elements M₁₁ₐ, M₁₂ₐ, . . . , M₃₃ₐ, M_{11b}, M_{12b}, . . . , M_{33b} is an implementation of magnetic memory element Mₓ of FIG. 2B, and each of selector elements S₁₁ₐ, S₁₂ₐ, . . . , S₃₃ₐ, S_{11b}, S_{12b}, . . . , S_{33b} is an implementation of selector element Sₓ of FIG. 2B.

Each memory cell 302₁₁ₐ, 302₁₂ₐ, . . . , 302₃₃ₐ has a first terminal coupled to one of bit lines BL1, BL2, BL3, and a second terminal coupled to one of word lines WL1a, WL2a, WL3a, and each memory cell 302_{11b}, 302_{12b}, . . . , 302_{33b} has a first terminal coupled to one of bit lines BL1, BL2, BL3, and a second terminal coupled to one of word lines WL1b, WL2b, WL3b. For example, memory cell 302₁₃ₐ includes magnetic memory element M₁₃ₐ coupled in series with selector element S₁₃ₐ, and includes a first terminal coupled to bit line BL3, and a second terminal coupled to word line WL1a.

Likewise, memory cell 302_{22b} includes magnetic memory element M_{22b} coupled in series with selector element S_{22b}, and includes a first terminal coupled to bit line BL2, and a second terminal coupled to word line WL2b. Similarly, memory cell 302₃₃ₐ includes magnetic memory element M₃₃ₐ coupled in series with selector element S₃₃ₐ, and includes a first terminal coupled to bit line BL3, and a second terminal coupled to word line WL3a.

Magnetic memory elements M₁₁ₐ, M₁₂ₐ, . . . , M₃₃ₐ may be disposed above or below corresponding selector elements S₁₁ₐ, S₁₂ₐ, . . . , S₃₃ₐ, respectively, and magnetic memory elements M_{11b}, M_{12b}, . . . , M_{33b}, may be disposed above or below corresponding selector elements S_{11b}, S_{12b}, . . . , S_{33b}, respectively. In an embodiment, the orientation of memory cells 302₁₁ₐ, 302₁₂ₐ, . . . , 302₃₃ₐ of first memory level 300a is the same as the orientation of memory cell 302_{11b}, 302_{12b}, . . . , 302_{33b} of second memory level 300b. In another embodiment, the orientation of memory cells 302₁₁ₐ, 302₁₂ₐ, . . . , 302₃₃ₐ of first memory level 300a is opposite the orientation of memory cell 302_{11b}, 302_{12b}, . . . , 302_{33b} of second memory level 300b.

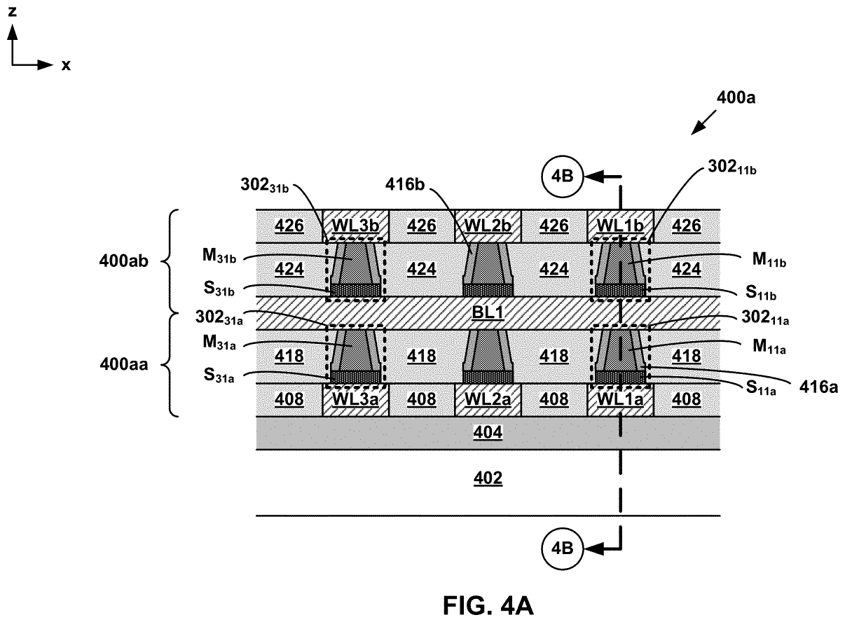

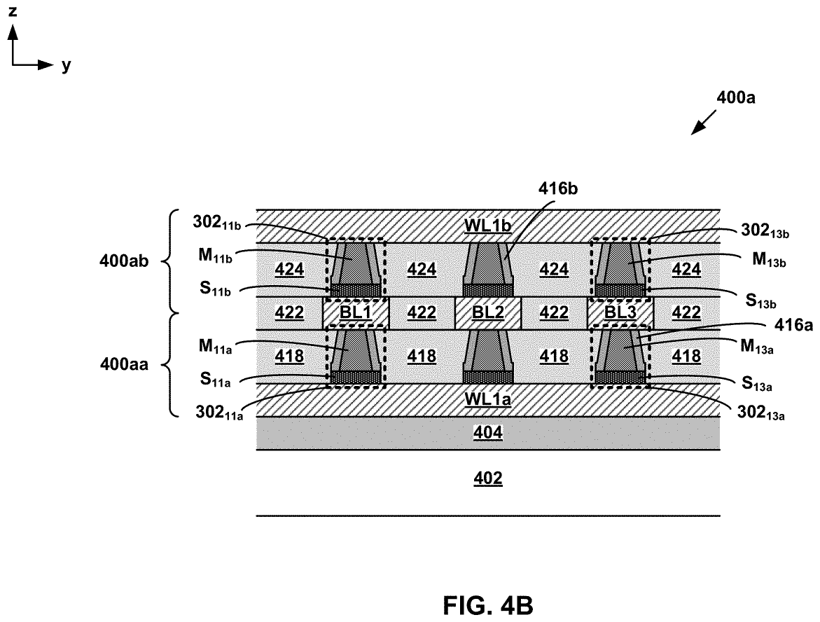

FIGS. 4A-4B depict various views of an embodiment of a cross-point memory array 400a that includes memory cells that each include a magnetic memory element coupled in series with a selector element. The physical structure depicted in FIGS. 4A-4B may include one implementation of cross-point memory array 300 of FIGS. 3A-3B.

Cross-point memory array 400a includes a first memory level 400aa (corresponding to first memory level 300a of FIG. 3A), and a second memory level 400ab (corresponding to second memory level 300b of FIG. 3B) positioned above first memory level 400aa. Cross-point memory array 400a may include more than two memory levels. Cross-point memory array 400a is an example of an implementation of memory array 160 in FIG. 1E.

Cross-point memory array 400a includes word lines WL1a, WL2a, WL3a, WL1b, WL2b and WL3b arranged in a first direction (e.g., an x-direction), and bit lines BL1, BL2, BL3 arranged in a second direction (e.g., a y-direction) perpendicular to the first direction. Persons of ordinary skill in the art will understand that cross-point memory arrays, such as cross-point memory array 400a may include more or fewer than six word lines, and three bit lines.

In an embodiment, cross-point memory array 400a includes word lines WL1a, WL2a, WL3a disposed above a substrate 402, such as a silicon, germanium, silicon-germanium, undoped, doped, bulk, SOI or other substrate with or without additional circuitry. In an embodiment, an isolation layer 404, such as a layer of silicon dioxide, silicon nitride, silicon oxynitride or any other suitable insulating layer, is disposed between substrate 402 and word lines WL1a, WL2a, WL3a. In an embodiment, word lines WL1a, WL2a, WL3a are formed of a conductive material (e.g., copper or other conductive material), and are separated from one another by a first dielectric material 408 (e.g., silicon dioxide or other similar dielectric material).

In an embodiment, memory cells 302₁₁ₐ, 302₁₂ₐ, . . . , 302₃₃ₐ are disposed above word lines WL1a, WL2a, WL3a. Each of memory cells 302₁₁ₐ, 302₁₂ₐ, . . . , 302₃₃ₐ includes a corresponding magnetic memory element M₁₁ₐ, M₁₂ₐ, . . . , M₃₃ₐ, respectively, coupled in series with a corresponding selector element S₁₁ₐ, S₁₂ₐ, . . . , S₃₃ₐ, respectively. In an embodiment, a portion of each magnetic memory element M₁₁ₐ, M₁₂ₐ, . . . , M₃₃ₐ, is encapsulated with a second dielectric material 416a (e.g., silicon nitride or other similar dielectric material). In an embodiment, memory cells 302₁₁ₐ, 302₁₂ₐ, . . . , 302₃₃ₐ are separated from one another by a third dielectric material 418 (e.g., silicon dioxide or other similar dielectric material). In an embodiment, each of memory cells 302₁₁ₐ, 302₁₂ₐ, . . . , 302₃₃ₐ are vertically-oriented.

In an embodiment, bit lines BL1, BL2, BL3 are disposed above memory cells 302₁₁ₐ, 302₁₂ₐ, . . . , 302₃₃ₐ. In an embodiment, bit lines BL1, BL2, BL3 are formed of a conductive material (e.g., copper or other conductive material), and are separated from one another by a fourth dielectric material 422 (e.g., silicon dioxide or other similar dielectric material). Each of memory cells 302₁₁ₐ, 302₁₂ₐ, . . . , 302₃₃ₐ is coupled to one of bit lines BL1, BL2, BL3, and to one of word lines WL1a, WL2a, WL3a.

In an embodiment, a memory cell is disposed between the intersection of each bit line and each word line. For example, memory cell 302₁₁ₐ is disposed between the intersection of bit line BL1 and word line WL1a, memory cell 302₂₁ₐ is disposed between the intersection of bit line BL1 and word line WL2a, memory cell 302₃₁ₐ is disposed between the intersection of bit line BL1 and word line WL3a, memory cell 302₁₂ₐ is disposed between the intersection of bit line BL2 and word line WL1a, memory cell 302₂₂ₐ is disposed between the intersection of bit line BL2 and word line WL2a, memory cell 302₃₂ₐ is disposed between the intersection of bit line BL2 and word line WL3a, memory cell 302₁₃ₐ is disposed between the intersection of bit line BL3 and word line WL1a, memory cell 302₂₃ₐ is disposed between the intersection of bit line BL3 and word line WL2a, and memory cell 302₃₃ₐ is disposed between the intersection of bit line BL3 and word line WL3a.

In an embodiment, memory cells 302_{11b}, 302_{12b}, . . . , 302_{33b} are disposed above bit lines BL1, BL2, BL3. Each of memory cells 302_{11b}, 302_{12b}, . . . , 302₃₃b includes a corresponding magnetic memory element M_{11b}, M_{12b}, . . . , M_{33b}, respectively, coupled in series with a corresponding selector element S_{11b}, S_{12b}, . . . , S_{33b}, respectively. In an embodiment, a portion of each magnetic memory element M_{11b}, M_{12b}, . . . , M_{33b}, is encapsulated with a fifth dielectric material 416b (e.g., silicon nitride or other similar dielectric material). In an embodiment, memory cells 302_{11b}, 302_{12b}, . . . , 302_{33b} are separated from one another by a sixth dielectric material 424 (e.g., silicon dioxide or other similar dielectric material). In an embodiment, each of memory cells 302_{11b}, 302_{12b}, . . . , 302_{33b} are vertically-oriented.

In an embodiment, word lines WL1b, WL2b, WL3b are disposed above memory cells 302_{11b}, 302_{12b}, . . . , 302_{33b}. In an embodiment, word lines WL1b, WL2b, WL3b are formed of a conductive material (e.g., copper or other conductive material), and are separated from one another by a seventh dielectric material 426 (e.g., silicon dioxide or other similar dielectric material). Each of memory cells 302_{11b}, 302_{12b}, . . . , 302_{33b} is coupled to one of bit lines BL1, BL2, BL3, and to one of word lines WL1b, WL2b, WL3b.

In an embodiment, a memory cell is disposed between the intersection of each bit line and each word line. For example, memory cell 302_{11b} is disposed between the intersection of bit line BL1 and word line WL1b, memory cell 302_{21b} is disposed between the intersection of bit line BL1 and word line WL2b, memory cell 302_{31b} is disposed between the intersection of bit line BL1 and word line WL3b, memory cell 302_{12b} is disposed between the intersection of bit line BL2 and word line WL1b, memory cell 302_{22b} is disposed between the intersection of bit line BL2 and word line WL2b, memory cell 302_{32b} is disposed between the intersection of bit line BL2 and word line WL3b, memory cell 302_{13b} is disposed between the intersection of bit line BL3 and word line WL1b, memory cell 302_{23b} is disposed between the intersection of bit line BL3 and word line WL2b, and memory cell 302_{33b} is disposed between the intersection of bit line BL3 and word line WL3b.

In the embodiment of cross-point memory array 400a depicted in FIGS. 4A-4B, memory cells 302₁₁ₐ, 302₁₂ₐ, . . . , 302₃₃ₐ of first memory level 400aa and memory cells 302_{11b}, 302_{12b}, . . . , 302_{33b} of second memory level 400ab have the same configuration, with selector elements S₁₁ₐ, S₁₂ₐ, . . . , S₃₃ₐ disposed below corresponding magnetic memory elements M₁₁ₐ, M₁₂ₐ, . . . , M₃₃ₐ, respectively, and selector elements S_{11b}, S_{12b}, . . . , S_{33b} disposed below corresponding magnetic memory elements M_{11b}, M_{12b}, . . . , M_{33b}, respectively.

In other embodiments, memory cells 302₁₁ₐ, 302₁₂ₐ, . . . , 302₃₃ₐ of first memory level 400aa and memory cells 302_{11b}, 302_{12b}, . . . 302_{33b} of second memory level 400ab need not have the same configuration. For example, in another embodiment, memory cells 302₁₁ₐ, 302₁₂ₐ, . . . , 302₃₃ₐ of first memory level 400aa may have selector elements S₁₁ₐ, S₁₂ₐ, . . . , S₃₃ₐ disposed below corresponding magnetic memory elements M₁₁ₐ, M₁₂ₐ, . . . , M₃₃ₐ, respectively, and memory cells 302_{11b}, 302_{12b}, . . . , 302_{33b} of second memory level 400ab may have selector elements S_{11b}, S_{12b}, . . . , S_{33b} disposed above corresponding magnetic memory elements M_{11b}, M_{12b}, . . . , M_{33b}, respectively.

In another embodiment, memory cells 302₁₁ₐ, 302₁₂ₐ, . . . , 302₃₃ₐ of first memory level 400aa may have selector elements S₁₁ₐ, S₁₂ₐ, . . . S₃₃ₐ disposed above corresponding magnetic memory elements M₁₁ₐ, M₁₂ₐ, . . . , M₃₃ₐ, respectively, and memory cells 302_{11b}, 302_{12b}, . . . , 302_{33b} of second memory level 400ab may have selector elements S_{11b}, S_{12b}, . . . , S_{33b} disposed below corresponding magnetic memory elements M_{11b}, M_{12b}, . . . , M_{33b}, respectively. In still another embodiment, memory cells 302₁₁ₐ, 302₁₂ₐ, . . . , 302₃₃ₐ of first memory level 400aa may have selector elements S₁₁ₐ, S₁₂ₐ, . . . , S₃₃ₐ disposed above corresponding magnetic memory elements M₁₁ₐ, M₁₂ₐ, . . . , M₃₃ₐ, respectively, and memory cells 302_{11b}, 302_{12b}, . . . , 302_{33b} of second memory level 400ab may have selector elements S_{11b}, S_{12b}, . . . , S_{33b} disposed above corresponding magnetic memory elements M_{11b}, M_{12b}, . . . , M_{33b}, respectively.

In an embodiment, magnetic memory elements M₁₁ₐ, M₁₂ₐ, . . . , M₃₃ₐ of first memory level 400aa each have a first current polarity required for writing (referred to herein as a “first magnetic writing polarity”), and magnetic memory elements M_{11b}, M_{12b}, . . . , M_{33b} of second memory level 400ab each have a second current polarity required for writing (referred to herein as a “second magnetic writing polarity”). In an embodiment, the first magnetic writing polarity is the same as the second magnetic writing polarity. For example, magnetic memory elements M₁₁ₐ, M₁₂ₐ, . . . , M₃₃ₐ of first memory level 400aa and magnetic memory elements M_{11b}, M_{12b}, . . . , M_{33b} of second memory level 400ab may all be top-pinned magnetic memory elements or may all be bottom-pinned magnetic memory elements. In another embodiment, the second magnetic writing polarity is opposite the first magnetic writing polarity. For example, magnetic memory elements M₁₁ₐ, M₁₂ₐ, . . . , M₃₃ₐ of first memory level 400aa may be top-pinned magnetic memory elements, and magnetic memory elements M_{11b}, M_{12b}, . . . , M_{33b} of second memory level 400ab may be bottom-pinned magnetic memory elements, or vice-versa.

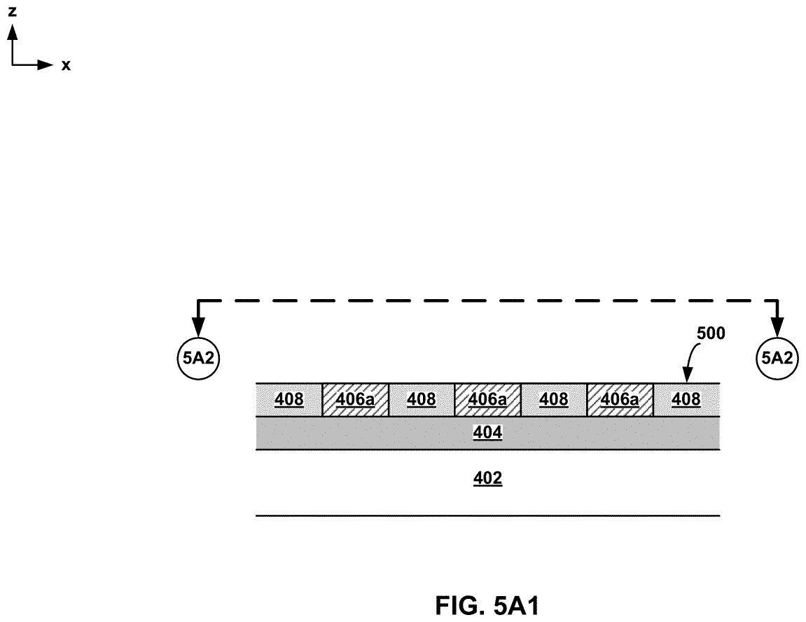

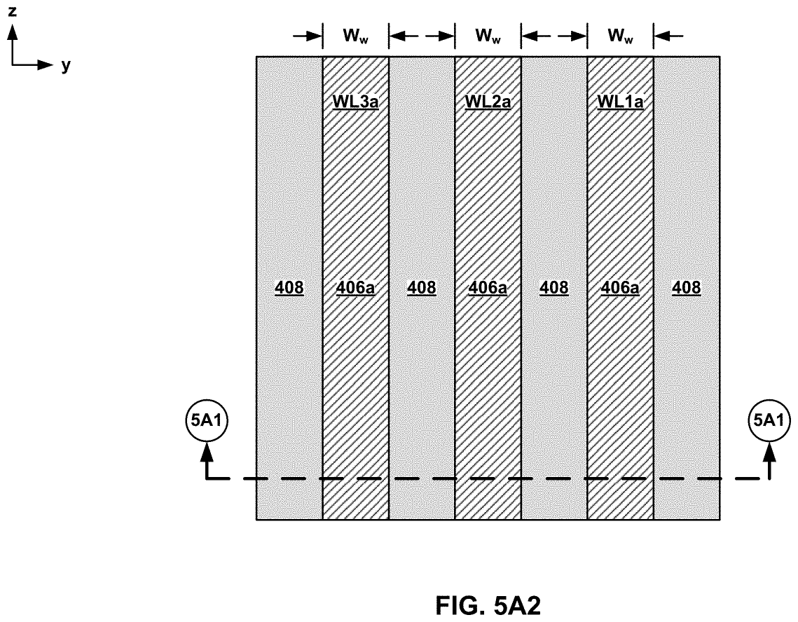

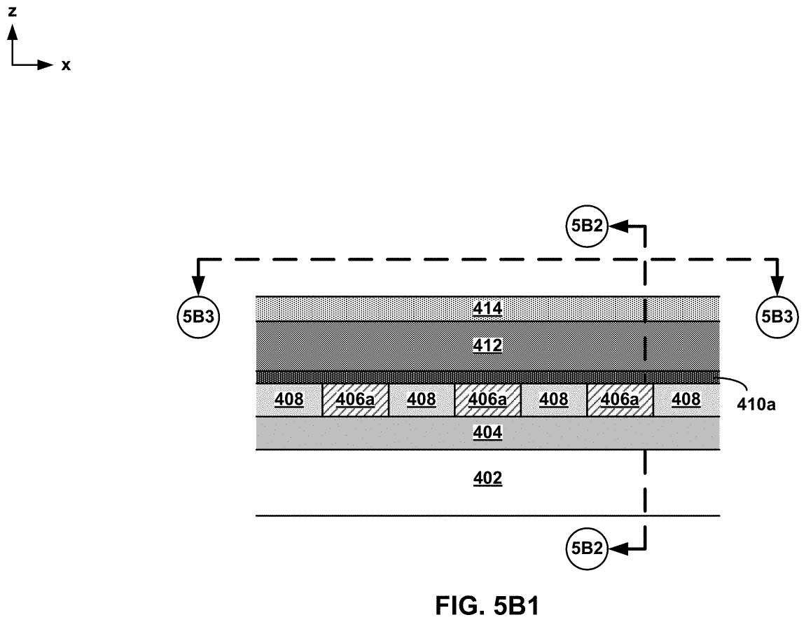

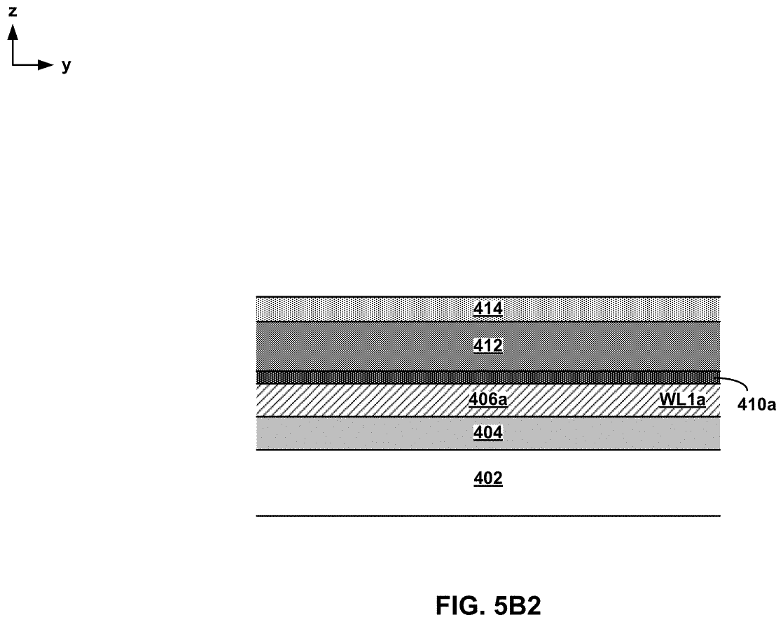

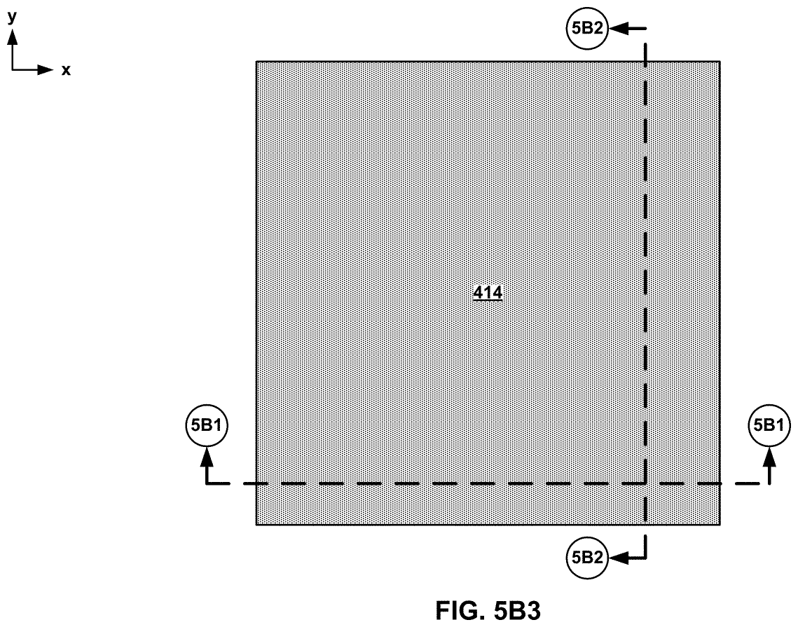

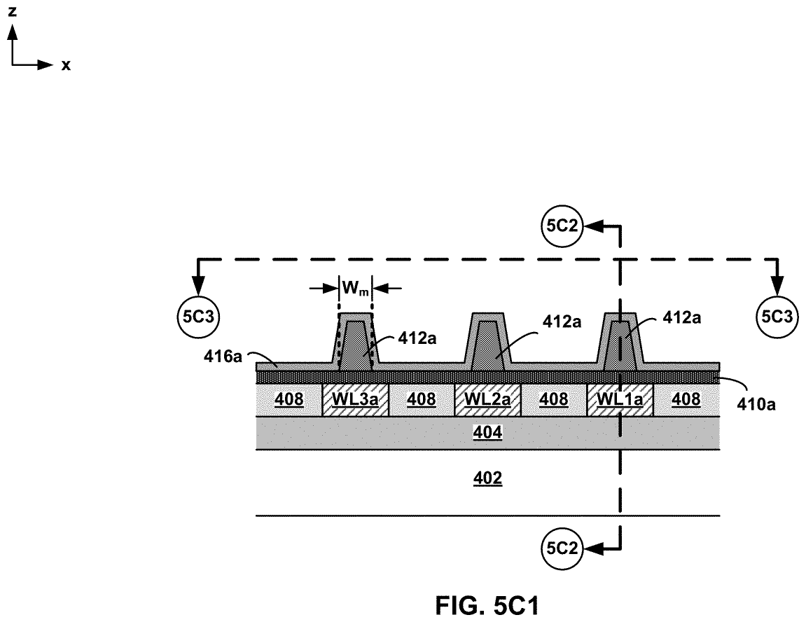

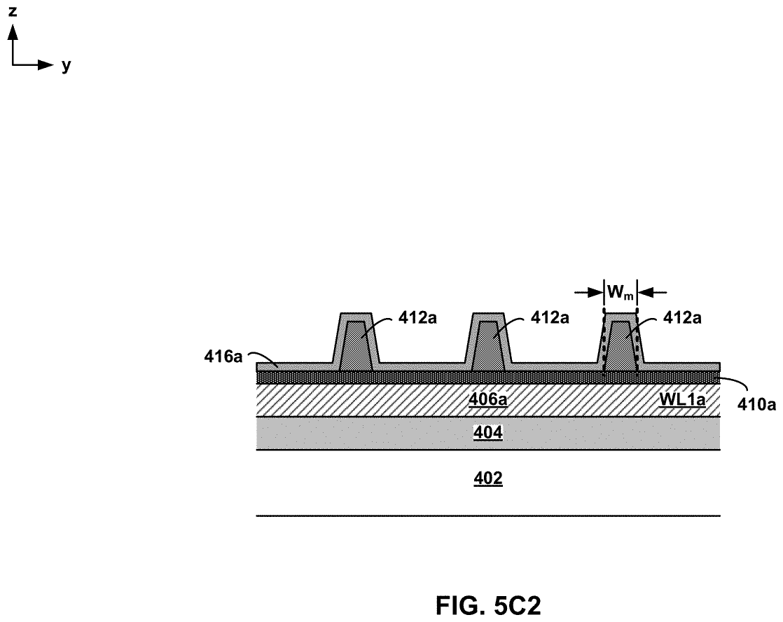

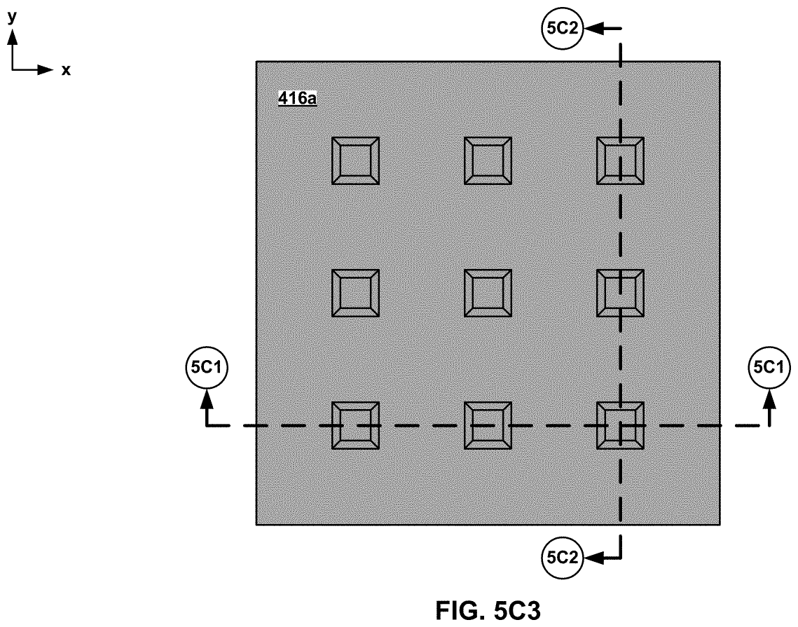

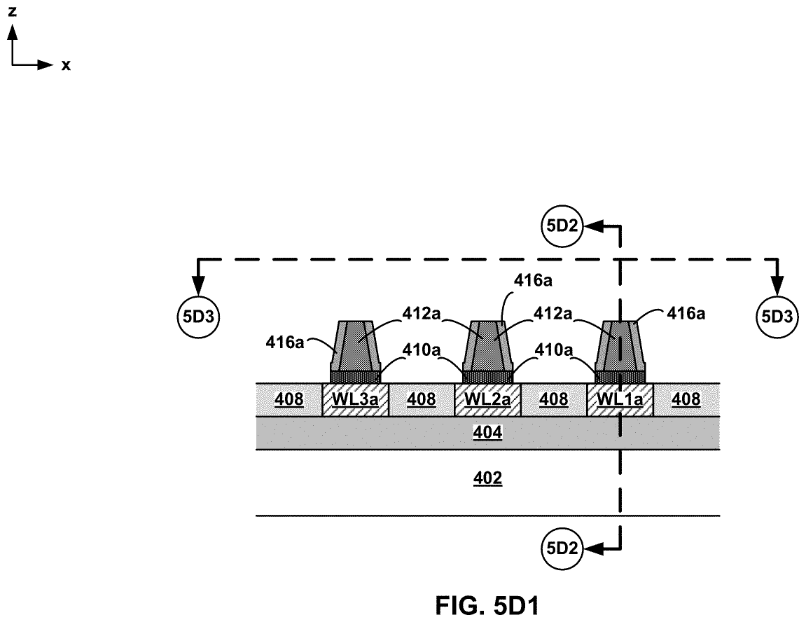

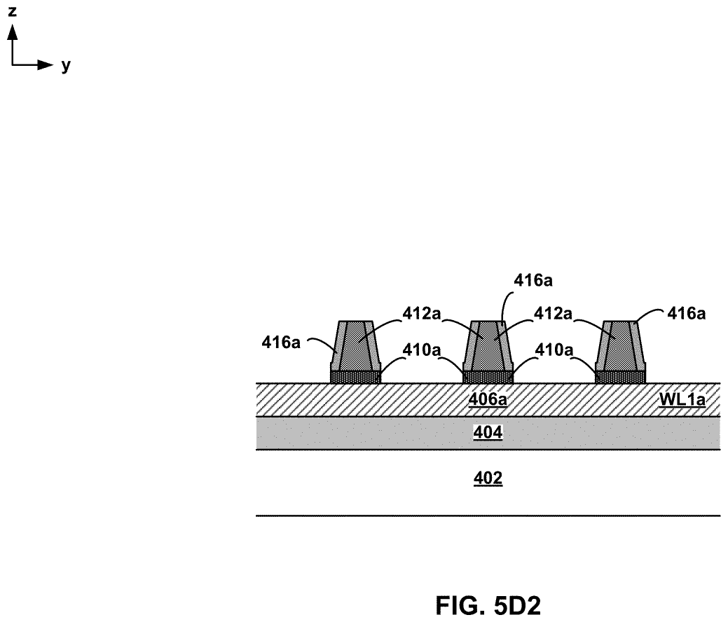

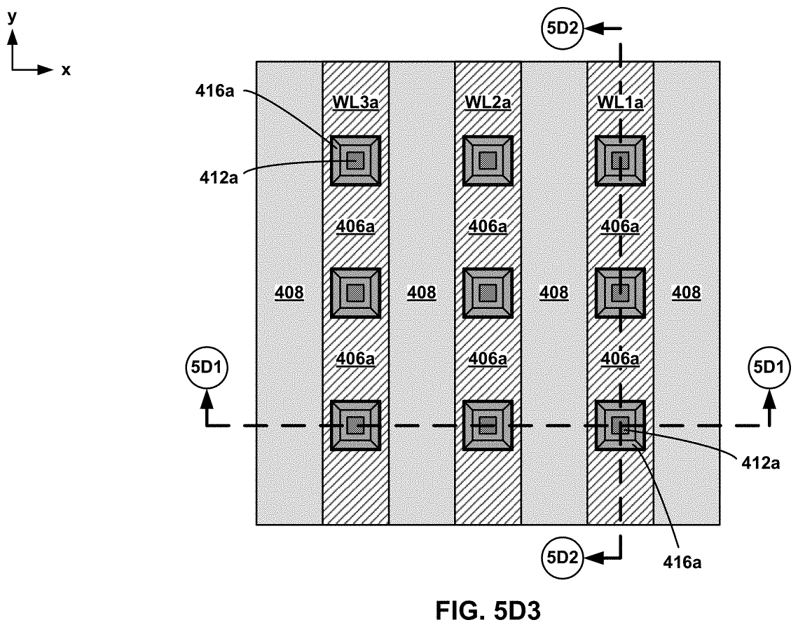

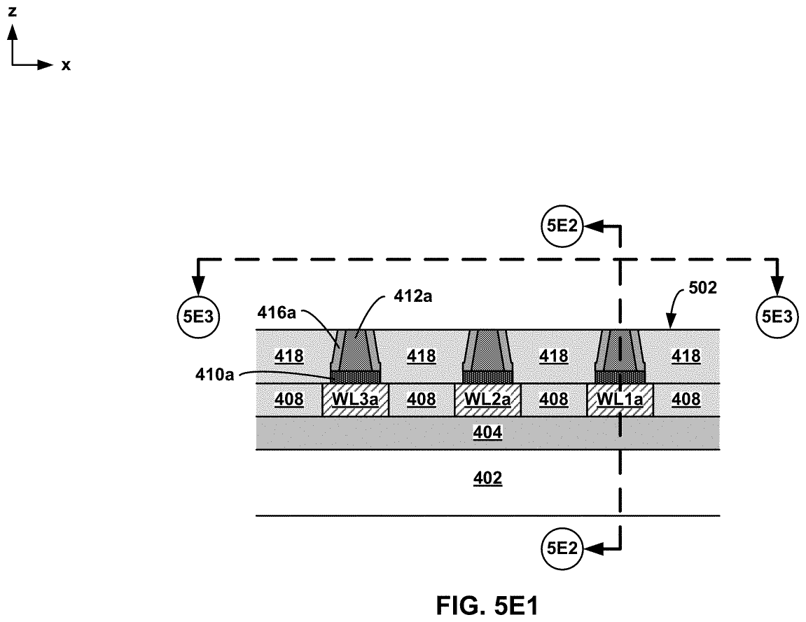

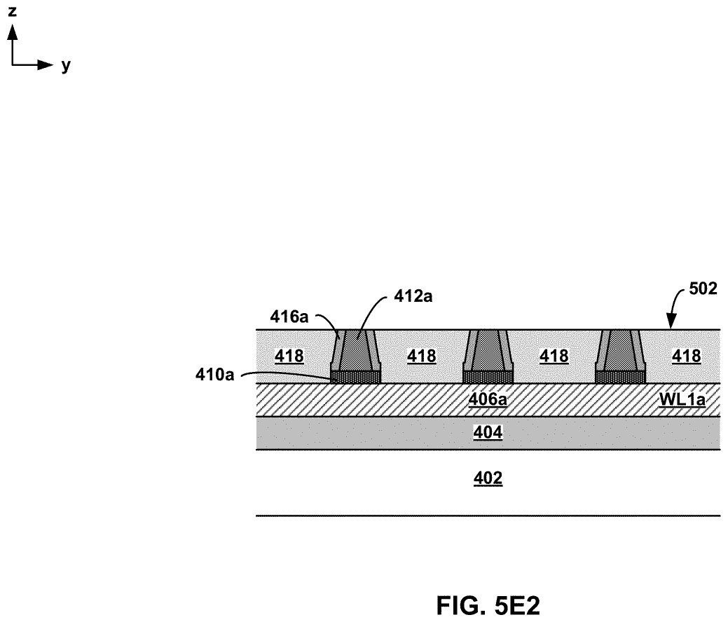

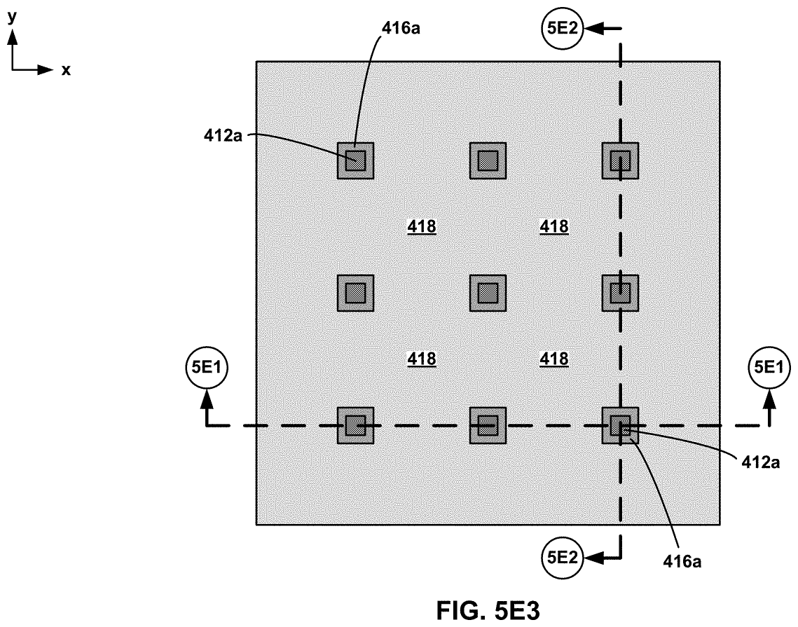

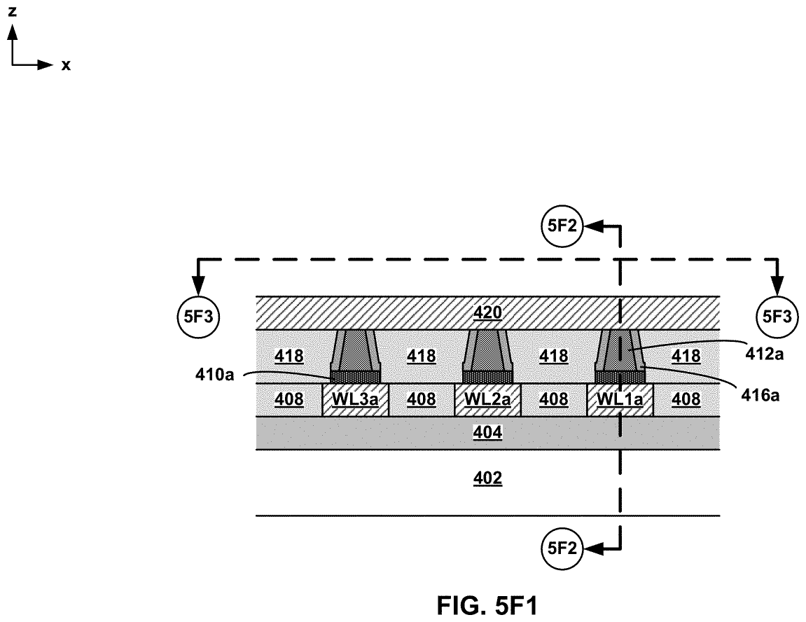

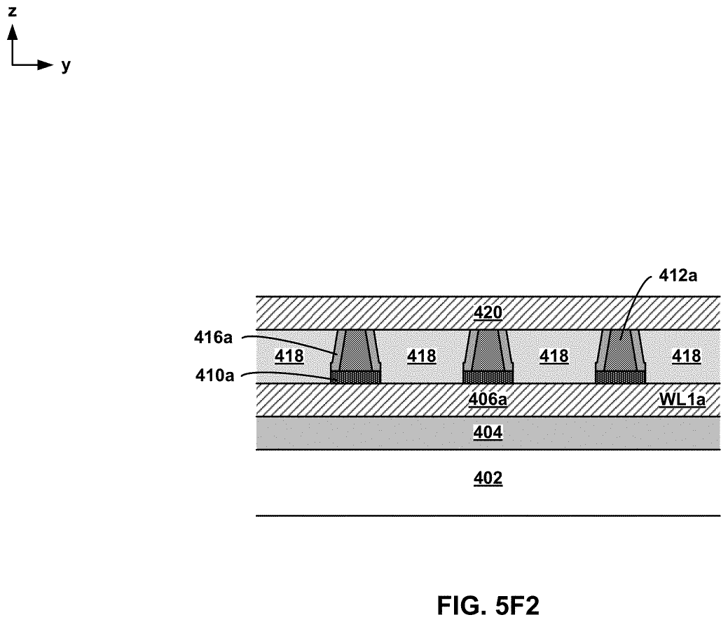

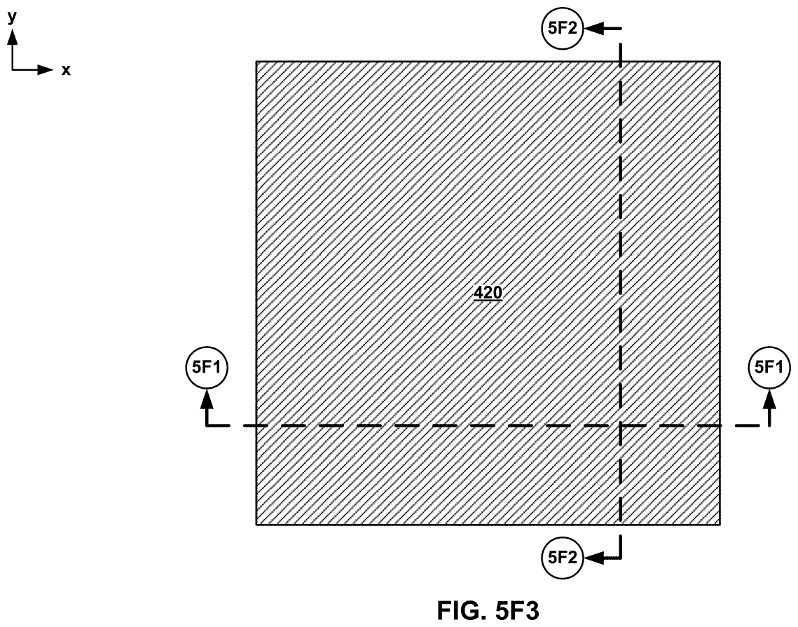

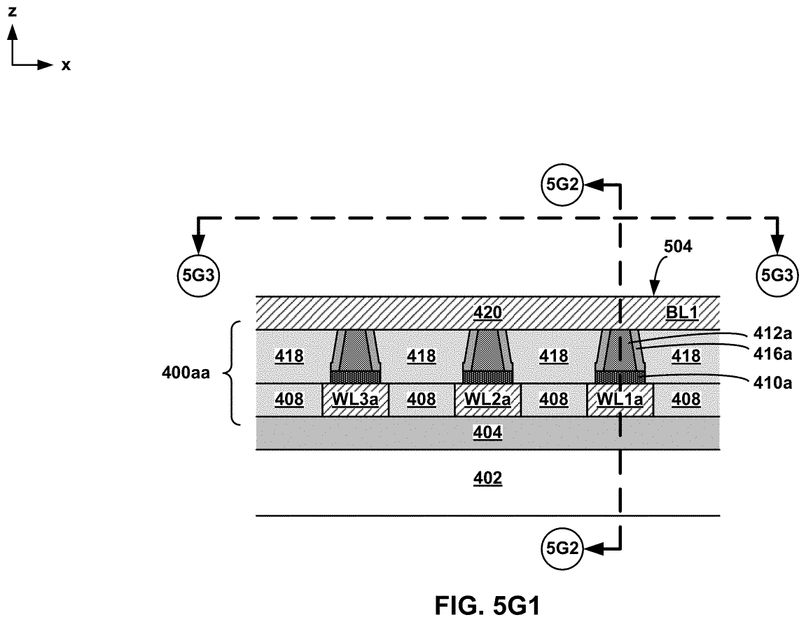

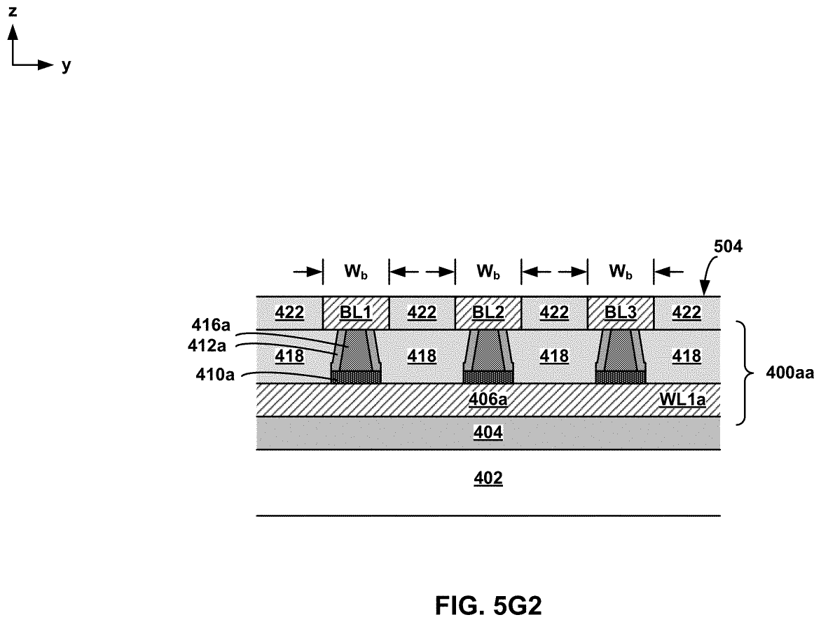

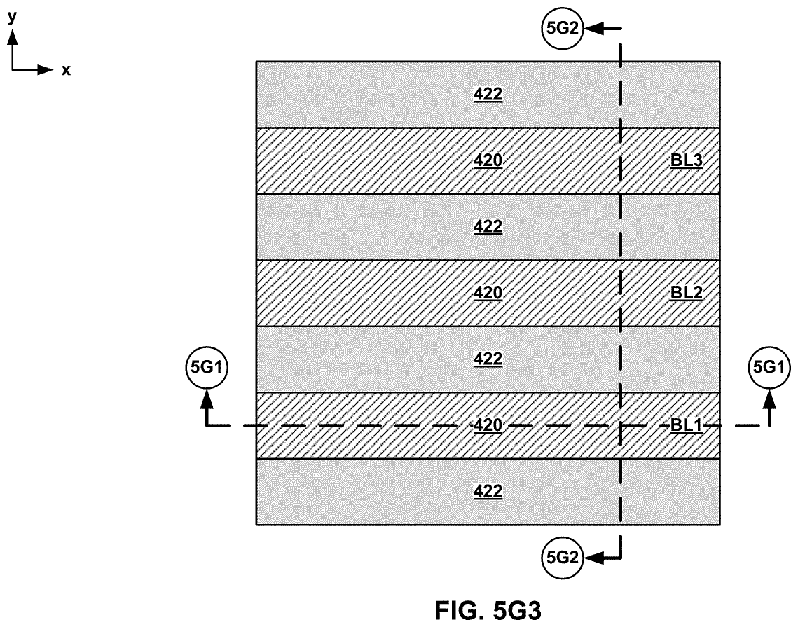

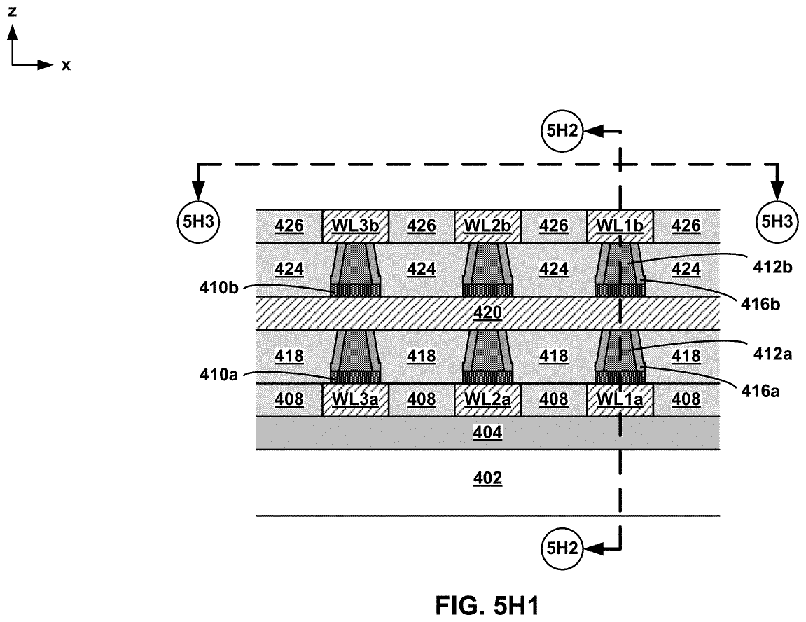

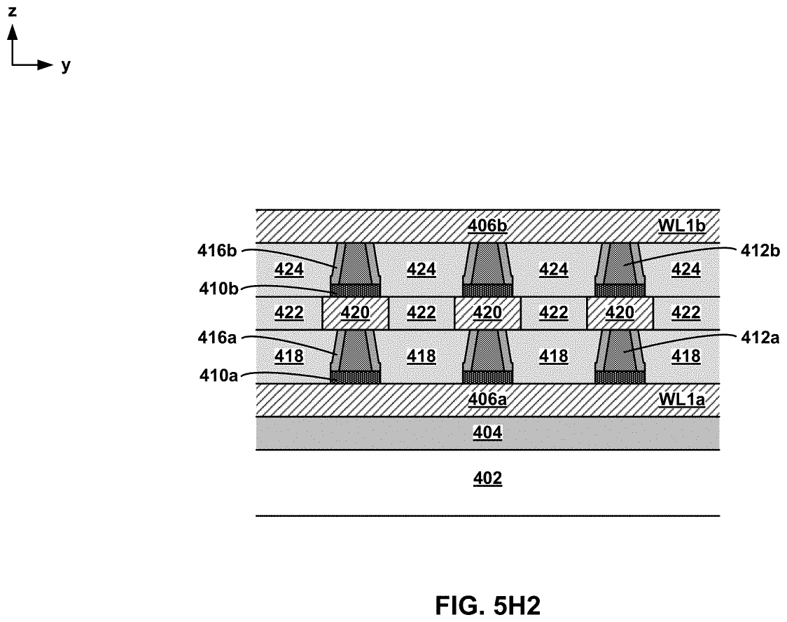

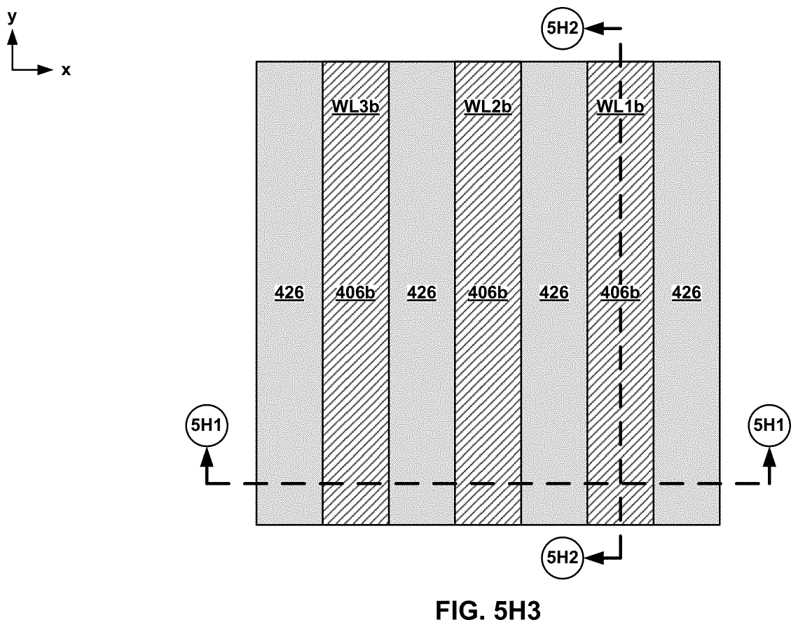

Referring now to FIGS. 5A1-5H3, an example method of forming a cross-point memory array is described. In particular, FIGS. 5A1-5H3 illustrate an example method of forming a cross-point memory array, such as cross-point memory array 400a of FIGS. 4A-4B. With reference to FIGS. 5A1-5A2, substrate 402 is shown as having already undergone several processing steps. Substrate 402 may be any suitable substrate such as a silicon, germanium, silicon-germanium, undoped, doped, bulk, silicon-on-insulator (SOI) or other substrate with or without additional circuitry. For example, substrate 402 may include one or more n-well or p-well regions (not shown). Isolation layer 404 is formed above substrate 402. In some embodiments, isolation layer 404 may be a layer of silicon dioxide, silicon nitride, silicon oxynitride or any other suitable insulating layer.

Following formation of isolation layer 404, a conductive layer 406a is deposited over isolation layer 404. Conductive layer 406a may include any suitable conductive material such as copper or another appropriate metal, heavily doped semiconductor material, a conductive silicide, a conductive silicide-germanide, a conductive germanide, or the like deposited by any suitable method (e.g., CVD, PVD, etc.). In at least one embodiment, conductive layer 406a may be copper having a thickness between about 20 nm and about 100 nm. Other conductive layer materials and/or thicknesses may be used. In some embodiments, an adhesion layer (not shown), such as titanium nitride or other similar adhesion layer material, may be disposed between isolation layer 404 and conductive layer 406a.

Conductive layer 406a is then patterned and etched. For example, conductive layer 406a may be patterned and etched using conventional lithography techniques, with a soft or hard mask, and wet or dry etch processing. In at least one embodiment, conductive layer 406a is patterned and etched to form substantially parallel, substantially co-planar word lines WL1a, WL2a, WL3a. Word lines WL1a, WL2a, WL3a each have a width W_{W}. Example widths W_{W} for word lines WL1a, WL2a, WL3a and/or spacings between word lines WL1a, WL2a, WL3a range between about 10 nm and about 60 nm, although other conductor widths and/or spacings may be used.

After word lines WL1a, WL2a, WL3a have been formed, a first dielectric material layer 408 is formed over substrate 402 to fill the voids between word lines WL1a, WL2a, WL3a. For example, approximately 50-300 nm of silicon dioxide may be deposited on substrate 402 and planarized using chemical mechanical polishing or an etchback process to form a planar surface 500. As depicted in FIGS. 5A1-5A2, first dielectric material layer 408 fills the gaps between word lines WL1a, WL2a, WL3a. Other dielectric materials such as silicon oxynitride, low K dielectrics, etc., and/or other dielectric material layer thicknesses may be used. Example low K dielectrics include carbon doped oxides, silicon carbon layers, or the like.

In other embodiments, word lines WL1a, WL2a, WL3a may be formed using a damascene process in which first dielectric material layer 408 is formed, patterned and etched to form etched trenches for word lines WL1a, WL2a, WL3a. The openings or voids then may be filled with conductive layer 406a. In such an embodiment, conductive layer 406a will line the bottom and sidewalls of each trench.

Following planarization, a first selector material layer 410a is deposited over substrate 402. First selector material layer 410a may be one or more chalcogenide materials, such as SiTe, GeAsSe, or similar materials that exhibit threshold switch behavior such as an Ovonic Threshold Switch. In other embodiments, first selector material layer 410a may be a volatile conductive bridge (VCB) type of selector comprised of HfOₓ doped with one or more of Ag, Pt, Au, Cu, or other metallic ion. In other embodiments, the selector could be a mixed-ionic electronic conduction (MIEC) or amorphous Indium Gallium Zinc Oxide (IGZO). In another embodiment, the selector is a Metal/amorphous semiconductor/Metal (MSM) type, with the amorphous semiconductor comprised of layers of a-Si and/or a-Ge. First selector material layer 410a may be deposited by any suitable method (e.g., CVD, PVD, etc.). In an embodiment, first selector material layer 410a may be between about 4 nm and about 30 nm of SiTe. In some embodiments, spacer electrode/buffer layers (e.g., TaN, TiN, W, carbon, carbon nitride) (not shown) may be deposited above and/or below first selector material layer 410a. In some embodiments, a capping layer (e.g., TaN) may be deposited on first selector material layer 410a, and then removed by chemical mechanical polishing prior to subsequent material deposition steps. Persons of ordinary skill in the art will understand that other selector materials, material thicknesses and/or other deposition techniques may be used.

Next, a magnetic memory material layer 412 is deposited over first selector material layer 410a. Magnetic memory material layer 412 may be deposited by any suitable method (e.g., CVD, PVD, etc.). In an embodiment, magnetic memory material layer 412 has a total thickness between about 15 nm and about 30 nm.

In an embodiment, magnetic material layer 412 includes a layer stack of multiple material layers. Table 1, below, provides an example magnetic material layer 412 layer stack (from bottom to top) having a bottom pinned layer PL:

TABLE 1

| Material | Example Thickness (nm) |
|---|---|
| Ta seed layer | 1 |
| Pt | 1 |
| alternating Co/Pt multilayer | 4 |
| CoFeB | 1 |
| Ru | 0.4 |
| CoFeB | 1 |
| MgO | 1 |
| CoFeB | 1.1 |
| MgO | 0.8 |
| Ta | 2 |
| Ru | 5 |

In this example, the CoFeB layer adjacent to the Co/Pt multilayer is the bottom pinned layer PL, and the CoFeB layer sandwiched between the MgO layers is the free layer.

Table 2, below, provides an example magnetic material layer 412 layer stack (from bottom to top) having a top pinned layer (PL):

TABLE 2

| Material | Example Thickness (nm) |
|---|---|
| Ta seed layer | 3 |
| MgO | 0.8 |
| CoFeB | 1.1 |
| MgO | 1 |
| CoFeB | 1 |
| Ru | 0.4 |
| CoFeB | 1 |
| alternating Co/Pt multilayer | 4 |
| Pt | 1 |
| Ta | 2 |
| Ru | 5 |

In this example, the CoFeB layer adjacent to the Co/Pt multilayer is the top pinned layer PL, and the CoFeB layer sandwiched between the MgO layers is the free layer.

In other embodiments, other materials, thicknesses, and numbers of layers may be used for magnetic material layer 412. In embodiments, one or more hard mask material layers (not shown) may be deposited above magnetic material layer 412. In an embodiment, a first hard mask layer (e.g., TaN or TiN) having a thickness between about 20 nm and about 80 nm is deposited on the layer stack

Next, a hard mask layer 414 is deposited over magnetic material layer 412, resulting in the structure shown in FIGS. 5B1-5B3. In an embodiment, hard mask layer 414 is a material that is very resistant to ion milling. In an embodiment, hard mask layer 414 is between about 20 nm and about 60 nm of diamond-like carbon (DLC). Other hard mask materials and/or thicknesses may be used. In an embodiment, hard mask layer 414 may be capped by a thin metal (e.g. Cr) or oxide (e.g. SiO2) to aid in transferring the resist pattern into the DLC and metallic hard mask layers using reactive ion etching (RIE)

Hard mask layer 414 (and any other hard mask material layers that were deposited above magnetic material layer 412) is patterned and etched (e.g., by RIE). Then, magnetic material layer 412 is etched (e.g., by ion milling) to form pillar-shaped magnetic material layer structures 412a, which are then encapsulated with a second dielectric material 416a that may be etched by RIE (e.g., SiNₓ, SiO₂, Al₂O₃, Ta₂O₅). For example, the milling may stop after etching to the top of first selector material layer 410a, and then between about 3 nm and about 15 nm of silicon nitride (SiNₓ) may be deposited it-situ on substrate 402, resulting in the structure shown in FIGS. 5C1-5C3. Without wanting to be bound by any particular theory, it is believed that second dielectric material 416a will protect magnetic material layer structures 412a from subsequent steps used to etch first selector material layer 410a.

As described in more detail below, in an embodiment, second dielectric material 416a may include multiple layers of dielectric materials. In an embodiment, magnetic material layer structures 412a have a maximum width Wₘ that is narrower than a width W_{W} of word lines WL1a, WL2a, WL3a. In embodiments, width Wₘ may be between about 10 nm and about 50 nm, although other widths may be used.

An anisotropic etch is used to remove lateral portions of second dielectric material 416a and first selector material layer 410a, leaving only sidewall portions of second dielectric material 416a on the sides of magnetic material layer structures 412a, and leaving only portions of first selector material layer 410a beneath magnetic material layer structures 412a, resulting in the structure shown in FIGS. 5D1-5D3. For example, an ion mill, a ME, or other suitable process may be used to anisotropically etch second dielectric material 416a and first selector material layer 410a. In an embodiment, second dielectric material 416a may include multiple layers of dielectric materials to achieve desired etch selectivities and profiles. In embodiments, the first and second hard mask layers (not shown) disposed above magnetic material layer 412 remain after etching second dielectric material 416a to prevent the etch from reducing a height of magnetic material layer structures 412a.

The portions of first selector material layer 410a beneath magnetic material layer structures 412a constitute selector elements S₁₁ₐ, S₁₂ₐ, . . . , S₃₃ₐ, and magnetic material layer structures 412a constitute magnetic memory element M₁₁ₐ, M₁₂ₐ, . . . , M₃₃ₐ. (See FIGS. 4A-4B).

A third dielectric material layer 418 is deposited over substrate 402, filling gaps between magnetic material layer structures 412a. For example, about 10 nm to about 80 nm of silicon dioxide may be deposited and planarized using chemical mechanical polishing or an etch-back process to expose top surfaces of magnetic material layer structures 412a and form a planar surface 502, resulting in the structure illustrated in FIGS. 5E1-5E3. Other dielectric materials such as silicon nitride, silicon oxynitride, high K dielectrics, etc., and/or other dielectric material layer thicknesses may be used.

Following planarization, a conductive layer 420 is deposited over planar surface 502, resulting in the structure shown in FIGS. 5F1-5F3. Conductive layer 420 may include any suitable conductive material such as copper or another appropriate metal, heavily doped semiconductor material, a conductive silicide, a conductive silicide-germanide, a conductive germanide, or the like deposited by any suitable method (e.g., CVD, PVD, etc.). In at least one embodiment, conductive layer 420 may be copper having a thickness between about 20 nm and about 100 nm. Other conductive layer materials and/or thicknesses may be used. In some embodiments, an adhesion layer (not shown), such as titanium nitride or other similar adhesion layer material, may be disposed between third dielectric material layer 418 and top surfaces of magnetic material layer structures 412a and conductive layer 420.

Conductive layer 420 is then patterned and etched. For example, conductive layer 420 may be patterned and etched using conventional lithography techniques, with a soft or hard mask, and wet or dry etch processing. In at least one embodiment, conductive layer 420 is patterned and etched to form substantially parallel, substantially co-planar bit lines BL1, BL2, BL3, each having a width W_{B}. Example widths W_{B} for bit lines BL1, BL2, BL3 and/or spacings between bit lines BL1, BL2, BL3 range between about 10 nm and about 60 nm, although other conductor widths and/or spacings may be used.

After bit lines BL1, BL2, BL3 have been formed, a fourth dielectric material layer 422 is formed over substrate 402 to fill the voids between bit lines BL1, BL2, BL3. For example, approximately 50-300 nm of silicon dioxide may be deposited on the substrate 402 and planarized using chemical mechanical polishing or an etchback process to form a planar surface 504, resulting in the structure shown in FIGS. 5G1-5G3. Other dielectric materials such as silicon oxynitride, low K dielectrics, etc., and/or other dielectric material layer thicknesses may be used.

As shown in FIGS. 5G1-5G3, first memory level 400aa is complete. The example processing steps described above are repeated to form second memory level 400ab above first memory level 400aa, resulting in the structure shown in FIGS. 5H1-5H3. Second memory level 400ab includes second selector material layers 410b disposed beneath magnetic material layer structures 412b, a fifth dielectric material 416b (e.g., silicon nitride or other similar dielectric material) disposed on sidewalls of magnetic material layer structures 412b, and a sixth dielectric material layer 424 (e.g., silicon dioxide) disposed between magnetic material layer structures 412b.

Second selector material layers 410b constitute selector elements S_{11b}, S_{12b}, . . . , S_{33b}, and magnetic material layer structures 412b constitute magnetic memory element M_{11b}, M_{12b}, . . . , M_{33b}. (See FIGS. 4A-4B). A conductive layer 406b (e.g., copper or another appropriate metal, heavily doped semiconductor material, a conductive silicide, a conductive silicide-germanide, a conductive germanide) is deposited over substrate 402, and then patterned and etched to form substantially parallel, substantially co-planar word lines WL1b, WL2b, WL3b, and a seventh dielectric material layer 426 is disposed between word lines WL1b, WL2b, WL3b.

As described above in connection with FIGS. 4A-4B, in an embodiment magnetic memory elements M₁₁ₐ, M₁₂ₐ, . . . , M₃₃ₐ of first memory level 400aa each have a first magnetic writing polarity, and magnetic memory elements M_{11b}, M_{12b}, . . . , M_{33b} of second memory level 400ab each have a second magnetic writing polarity. In an embodiment, the first magnetic writing polarity is the same as the second magnetic writing polarity. In another embodiment, the second magnetic writing polarity is opposite the first magnetic writing polarity. In the process steps described above and depicted in FIGS. 5A1-5H3, the magnetic writing polarities of the magnetic memory elements M₁₁ₐ, M₁₂ₐ, . . . , M₃₃ₐ of first memory level 400aa and magnetic memory elements M_{11b}, M_{12b}, . . . , M_{33b} of second memory level 400ab may be set based on the deposition order (e.g., bottom-pinned as described above and depicted in Table 1, or top-pinned as described above and depicted in Table 2) of material layers of magnetic material layer 412 for first memory level 400aa and second memory level 400ab.

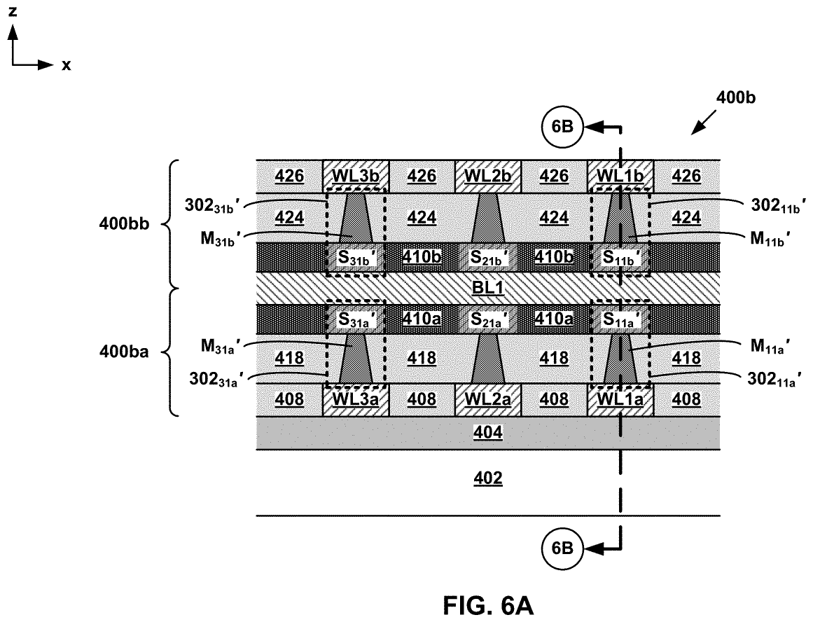

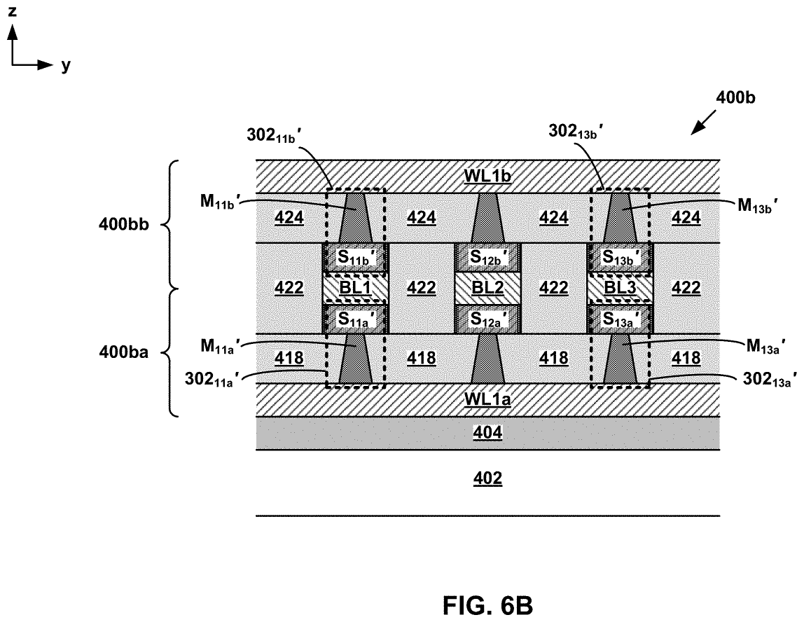

FIGS. 6A-6B depict various views of another embodiment of a cross-point memory array 400b that includes memory cells that each include a magnetic memory element coupled in series with a selector element. The physical structure depicted in FIGS. 6A-6B may include one implementation of cross-point memory array 300 of FIGS. 3A-3B.

Cross-point memory array 400b includes a first memory level 400ba (corresponding to first memory level 300a of FIG. 3A), and a second memory level 400bb (corresponding to second memory level 300b of FIG. 3B) positioned above first memory level 400ba. Cross-point memory array 400b may include more than two memory levels. Cross-point memory array 400b is an example of an implementation of memory array 160 in FIG. 1E.

Cross-point memory array 400b includes word lines WL1a, WL2a, WL3a, WL1b, WL2b and WL3b arranged in a first direction (e.g., an x-direction), and bit lines BL1, BL2, BL3 arranged in a second direction (e.g., a y-direction) perpendicular to the first direction. Persons of ordinary skill in the art will understand that cross-point memory arrays, such as cross-point memory array 400b may include more or fewer than six word lines, and three bit lines.

In an embodiment, cross-point memory array 400b includes word lines WL1a, WL2a, WL3a disposed above a substrate 402, such as a silicon, germanium, silicon-germanium, undoped, doped, bulk, SOI or other substrate with or without additional circuitry. In an embodiment, isolation layer 404, such as a layer of silicon dioxide, silicon nitride, silicon oxynitride or any other suitable insulating layer, is disposed between substrate 402 and word lines WL1a, WL2a, WL3a. In an embodiment, word lines WL1a, WL2a, WL3a are formed of a conductive material (e.g., copper or other conductive material), and are separated from one another by first dielectric material 408 (e.g., silicon dioxide or other similar dielectric material).

In an embodiment, memory cells 302₁₁ₐ′, 302₁₂ₐ′, . . . , 302₃₃ₐ′ are disposed above word lines WL1a, WL2a, WL3a. Each of memory cells 302₁₁ₐ′, 302₁₂ₐ′, . . . , 302₃₃ₐ′ includes a corresponding magnetic memory element M₁₁ₐ′, M₁₂ₐ′, . . . , M₃₃ₐ′, respectively, coupled in series with a corresponding selector element S₁₁ₐ′, S₁₂ₐ′, . . . , S₃₃ₐ′, respectively. In an embodiment, memory cells 302₁₁ₐ′, 302₁₂ₐ′, . . . , 302₃₃ₐ′ are separated from one another by third dielectric material 418 (e.g., silicon dioxide or other similar dielectric material). In an embodiment, each of memory cells 302₁₁ₐ′, 302₁₂ₐ′, . . . , 302₃₃ₐ′ are vertically-oriented.

In an embodiment, bit lines BL1, BL2, BL3 are disposed above memory cells 302₁₁ₐ′, 302₁₂ₐ′, . . . , 302₃₃ₐ′. In an embodiment, bit lines BL1, BL2, BL3 are formed of a conductive material (e.g., tungsten or other conductive material), and are separated from one another by a fourth dielectric material 422 (e.g., silicon dioxide or other similar dielectric material). Each of memory cells 302₁₁ₐ′, 302₁₂ₐ′, . . . , 302₃₃ₐ′ is coupled to one of bit lines BL1, BL2, BL3, and to one of word lines WL1a, WL2a, WL3a.

In an embodiment, first selector material layers 410a are formed as rows disposed beneath bit lines BL1, BL2, BL3. Thus, in an embodiment, selector elements S₁₁ₐ′, S₁₂ₐ′, . . . , S₃₃ₐ′ are portions (shown in cross-hatch) of rows of first selector material layers 410a, and are not separately patterned and etched for each individual memory cell 302₁₁ₐ′, 302₁₂ₐ′, . . . , 302₃₃ₐ′. Without wanting to be bound by any particular theory, it is believed that because first selector material layers 410a have a very high resistance when the selector material is an OFF state (i.e., not selected), there will be very little crosstalk between adjacent memory cells, and thus first selector material layers 410a need not be separately patterned and etched for each individual memory cell 302₁₁ₐ′, 302₁₂ₐ′, . . . , 302₃₃ₐ′. In other embodiments, first selector material layers 410a may be separately patterned and etched to form separate selector elements S₁₁ₐ′, S₁₂ₐ′, . . . , S₃₃ₐ′ for memory cells 302₁₁ₐ′, 302₁₂ₐ′, . . . , 302₃₃ₐ′, respectively.

In an embodiment, a memory cell is disposed between the intersection of each bit line and each word line. For example, memory cell 302₁₁ₐ′ is disposed between the intersection of bit line BL1 and word line WL1a, memory cell 302₂₁ₐ′ is disposed between the intersection of bit line BL1 and word line WL2a, memory cell 302₃₁ₐ′ is disposed between the intersection of bit line BL1 and word line WL3a, memory cell 302₁₂ₐ′ is disposed between the intersection of bit line BL2 and word line WL1a, memory cell 302₂₂ₐ′ is disposed between the intersection of bit line BL2 and word line WL2a, memory cell 302₃₂ₐ′ is disposed between the intersection of bit line BL2 and word line WL3a, memory cell 302₁₃ₐ′ is disposed between the intersection of bit line BL3 and word line WL1a, memory cell 302₂₃ₐ′ is disposed between the intersection of bit line BL3 and word line WL2a, and memory cell 302₃₃ₐ′ is disposed between the intersection of bit line BL3 and word line WL3a.

In an embodiment, memory cells 302_{11b}′, 302_{12b}′, . . . , 302_{33b}′ are disposed above bit lines BL1, BL2, BL3. Each of memory cells 302_{11b}′, 302_{12b}′, . . . , 302_{33b}′ includes a corresponding magnetic memory element M_{11b}′, M_{12b}′, . . . , M_{33b}′, respectively, coupled in series with a corresponding selector element S_{11b}′, S_{12b}′, . . . , S_{33b}′, respectively. In an embodiment, memory cells 302_{11b}′, 302_{12b}′, . . . , 302_{33b}′ are separated from one another by sixth dielectric material 424 (e.g., silicon dioxide or other similar dielectric material). In an embodiment, each of memory cells 302_{11b}′, 302_{12b}′, . . . , 302_{33b}′ are vertically-oriented.

In an embodiment, second selector material layers 410b are formed as rows disposed above bit lines BL1, BL2, BL3. Thus, in an embodiment, selector elements S_{11b}′, S_{12b}′, . . . , S_{33b}′ are portions (shown in cross-hatch) of rows of second selector material layers 410b, and are not separately patterned and etched for each individual memory cell 302_{11b}′, 302_{12b}′, . . . , 302_{33b}′. Without wanting to be bound by any particular theory, it is believed that because second selector material layers 410b have a very high resistance when the selector material is an OFF state (i.e., not selected), there will be very little crosstalk between adjacent memory cells, and thus second selector material layers 410b need not be separately patterned and etched for each individual memory cell 302_{11b}′, 302_{12b}′, . . . , 302_{33b}′. In other embodiments, second selector material layers 410b may be separately patterned and etched to form separate selector elements S_{11b}′, S_{12b}′, . . . , S_{33b}′ for memory cells 302_{11b}′, 302_{12b}′, . . . , 302_{33b}′, respectively.

In an embodiment, word lines WL1b, WL2b, WL3b are disposed above memory cells 302_{11b}′, 302_{12b}′, . . . , 302_{33b}′. In an embodiment, word lines WL1b, WL2b, WL3b are formed of a conductive material (e.g., copper or other conductive material), and are separated from one another by seventh dielectric material 426 (e.g., silicon dioxide or other similar dielectric material). Each of memory cells 302_{11b}′, 302_{12b}′, . . . , 302_{33b}′ is coupled to one of bit lines BL1, BL2, BL3, and to one of word lines WL1b, WL2b, WL3b.

In an embodiment, a memory cell is disposed between the intersection of each bit line and each word line. For example, memory cell 302_{11b}′ is disposed between the intersection of bit line BL1 and word line WL1b, memory cell 302_{21b}′ is disposed between the intersection of bit line BL1 and word line WL2b, memory cell 302_{31b}′ is disposed between the intersection of bit line BL1 and word line WL3b, memory cell 302_{12b}′ is disposed between the intersection of bit line BL2 and word line WL1b, memory cell 302_{22b}′ is disposed between the intersection of bit line BL2 and word line WL2b, memory cell 302_{32b}′ is disposed between the intersection of bit line BL2 and word line WL3b, memory cell 302_{13b}′ is disposed between the intersection of bit line BL3 and word line WL1b, memory cell 302_{23b}′ is disposed between the intersection of bit line BL3 and word line WL2b, and memory cell 302_{33b}′ is disposed between the intersection of bit line BL3 and word line WL3b.

In an embodiment, magnetic memory elements M₁₁ₐ′, M₁₂ₐ′, . . . , M₃₃ₐ′ of first memory level 400ba have a first magnetic writing polarity, and magnetic memory elements M_{11b}′, M_{12b}′, . . . , M_{33b}′ of second memory level 400bb each have a second magnetic writing polarity. In an embodiment, the first magnetic writing polarity is the same as the second magnetic writing polarity. For example, magnetic memory elements M₁₁ₐ′, M₁₂ₐ′, . . . , M₃₃ₐ′ of first memory level 400ba and magnetic memory elements M_{11b}′, M_{12b}′, . . . , M_{33b}′ of second memory level 400bb may all be top-pinned magnetic memory elements or may all be bottom-pinned magnetic memory elements. In another embodiment, the second magnetic writing polarity is opposite the first magnetic writing polarity. For example, magnetic memory elements M₁₁ₐ′, M₁₂ₐ′, . . . , M₃₃ₐ′ of first memory level 400ba may be top-pinned magnetic memory elements, and magnetic memory elements M_{11b}′, M_{12b}′, . . . , M_{33b}′ of second memory level 400bb may be bottom-pinned magnetic memory elements, or vice-versa.

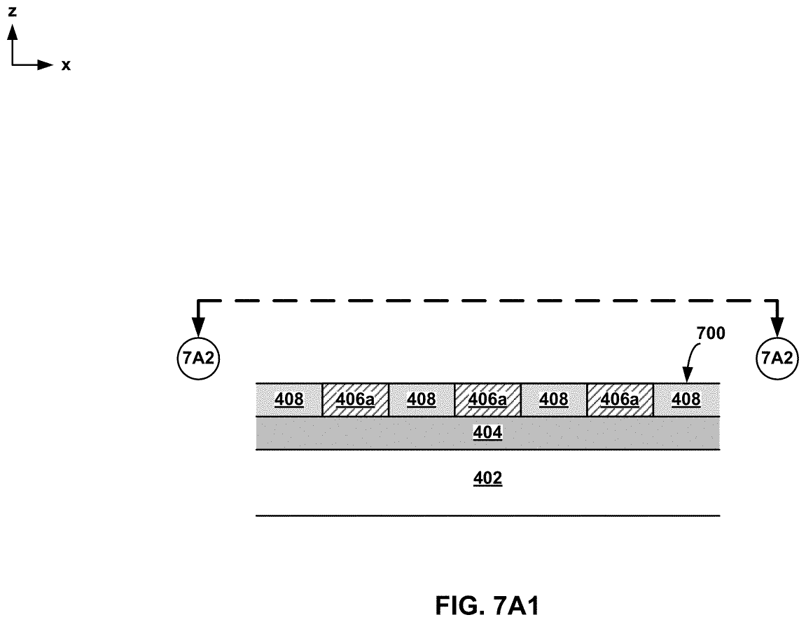

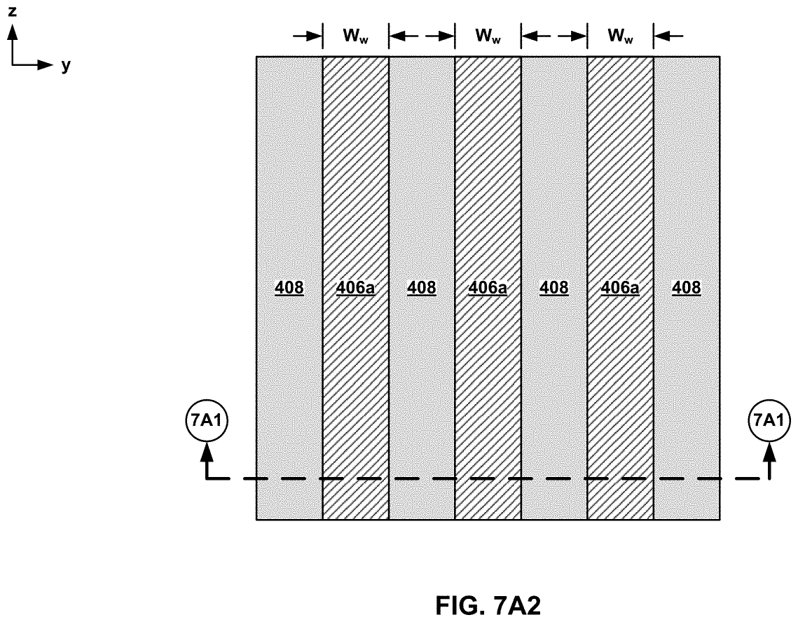

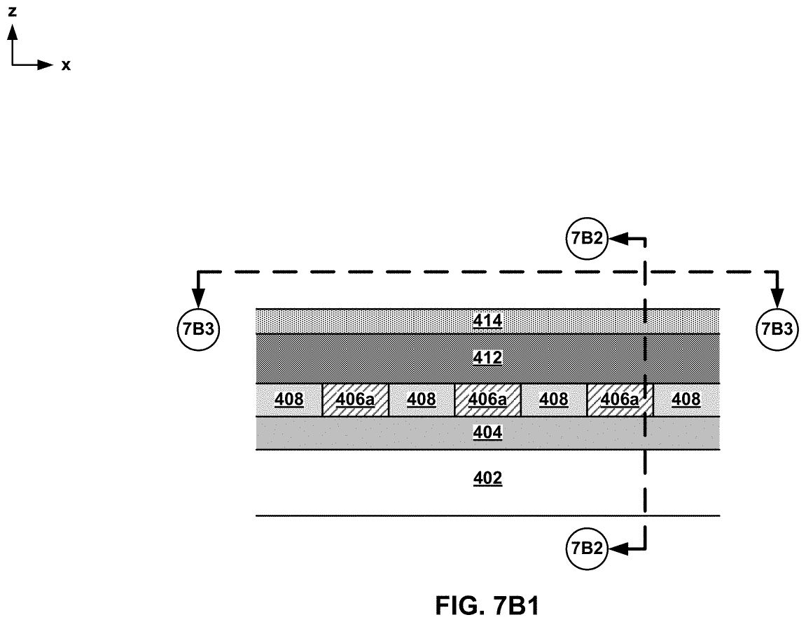

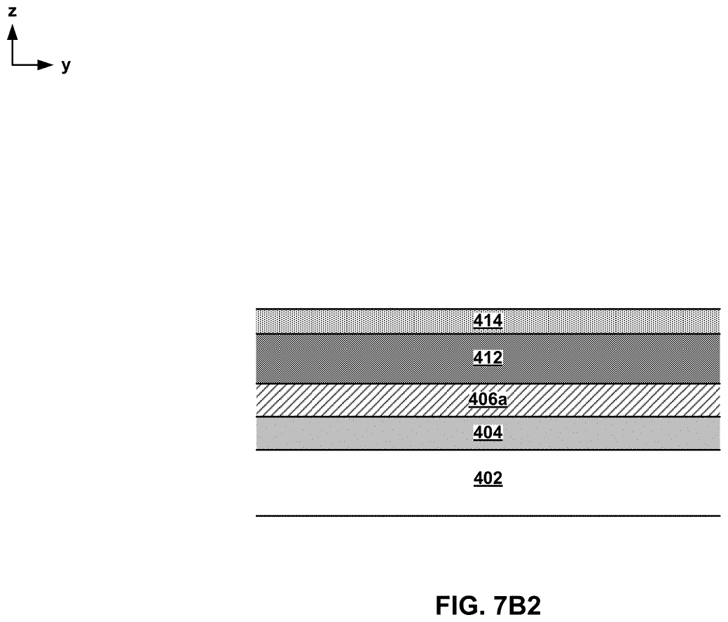

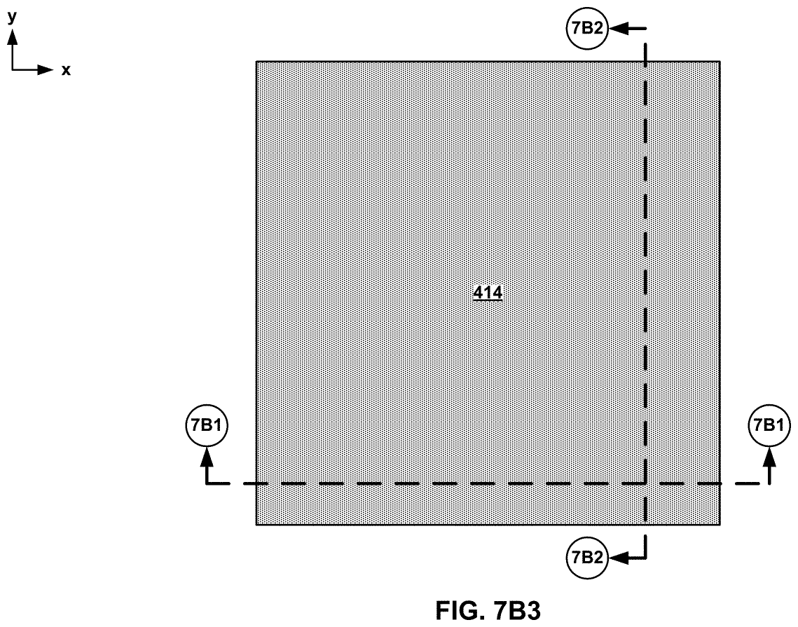

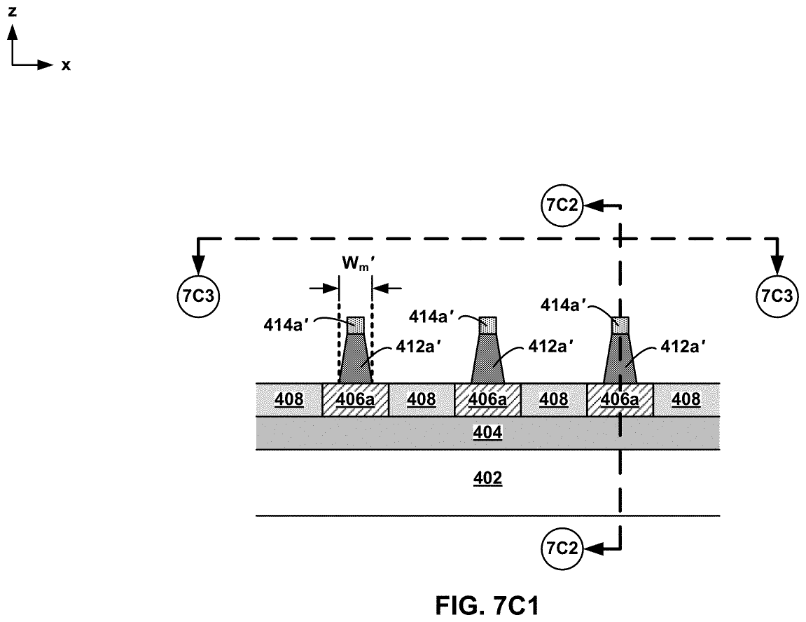

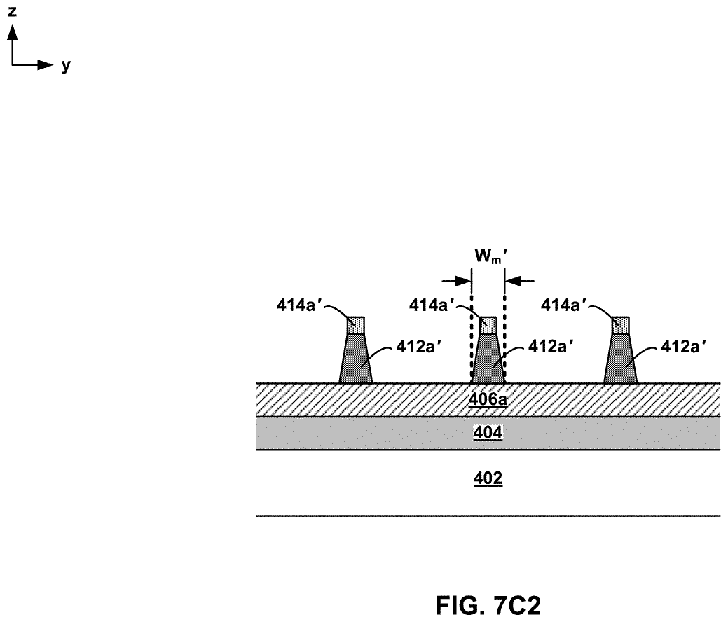

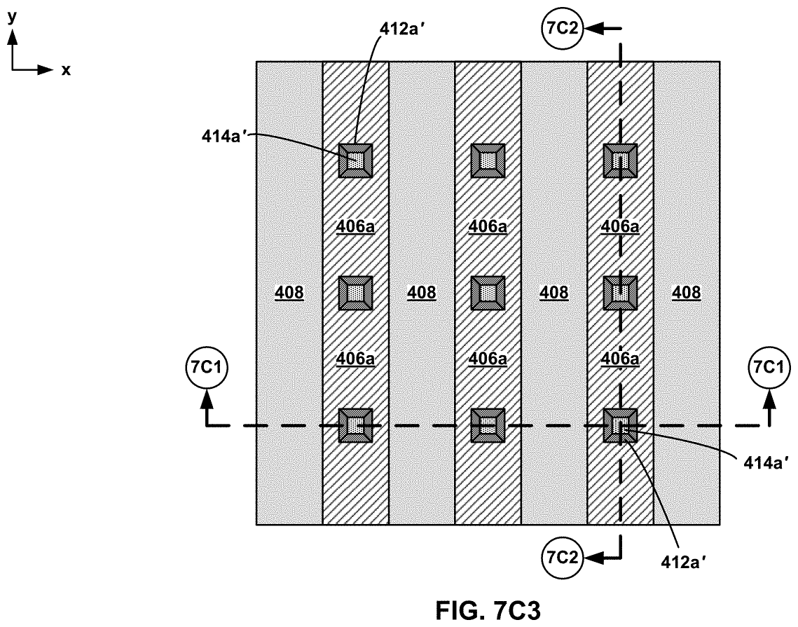

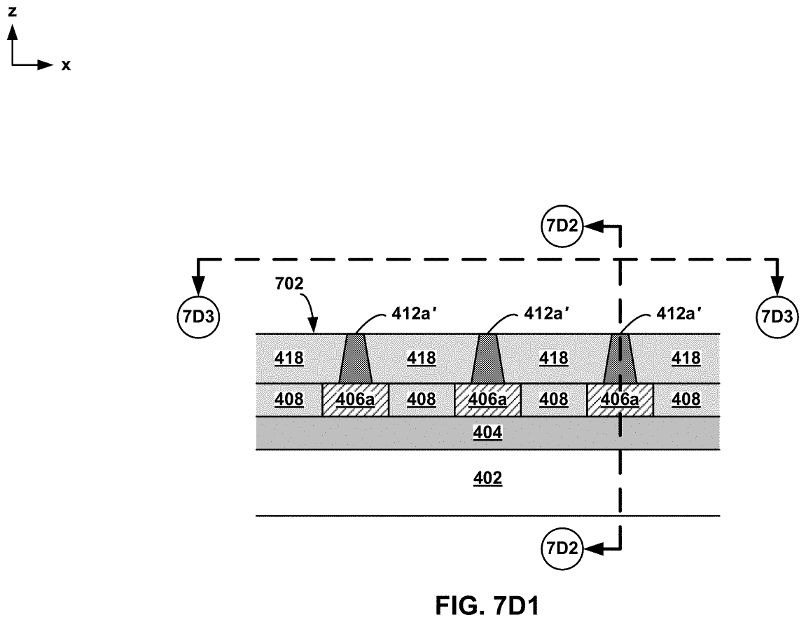

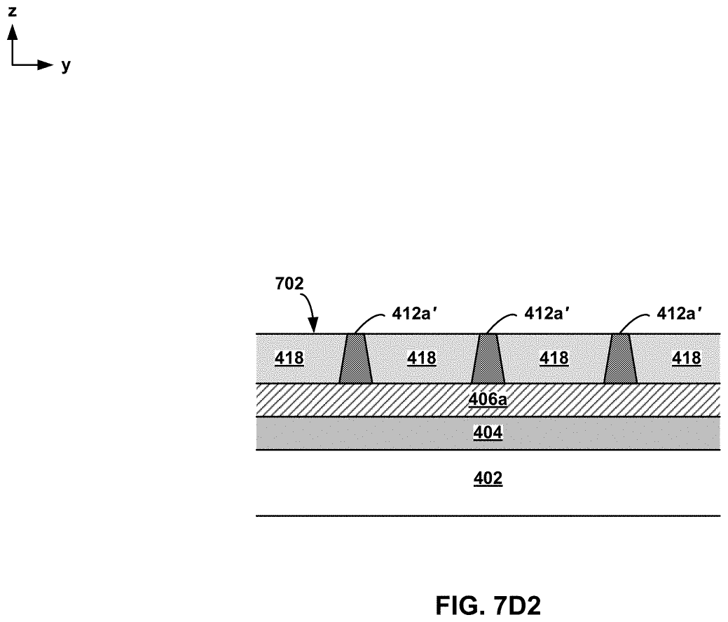

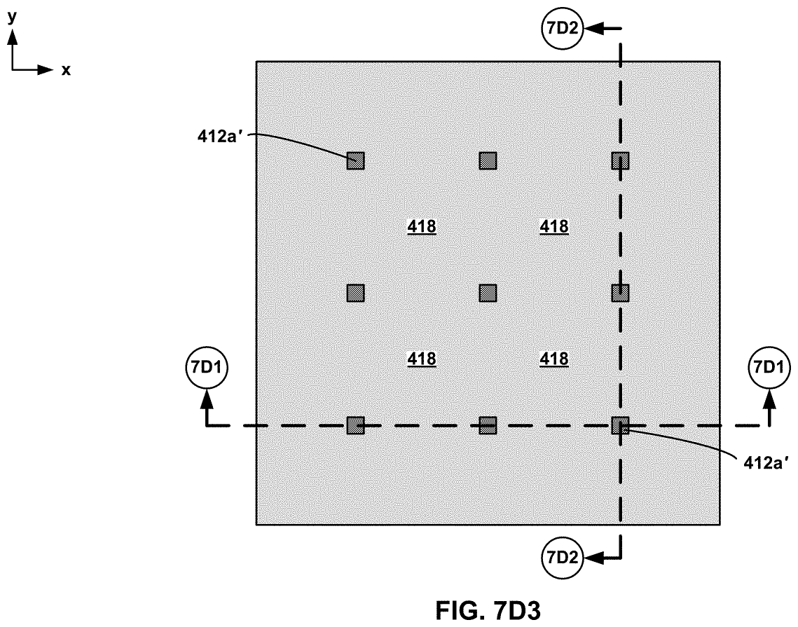

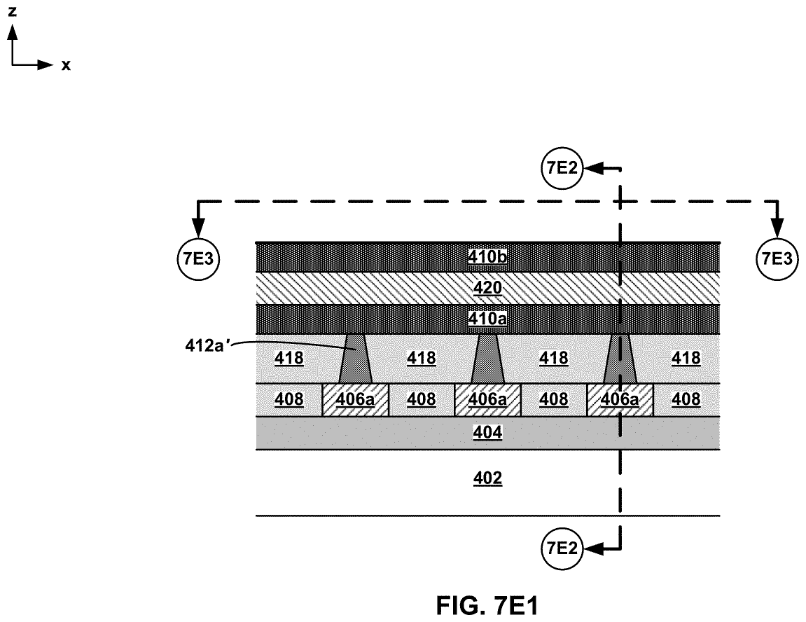

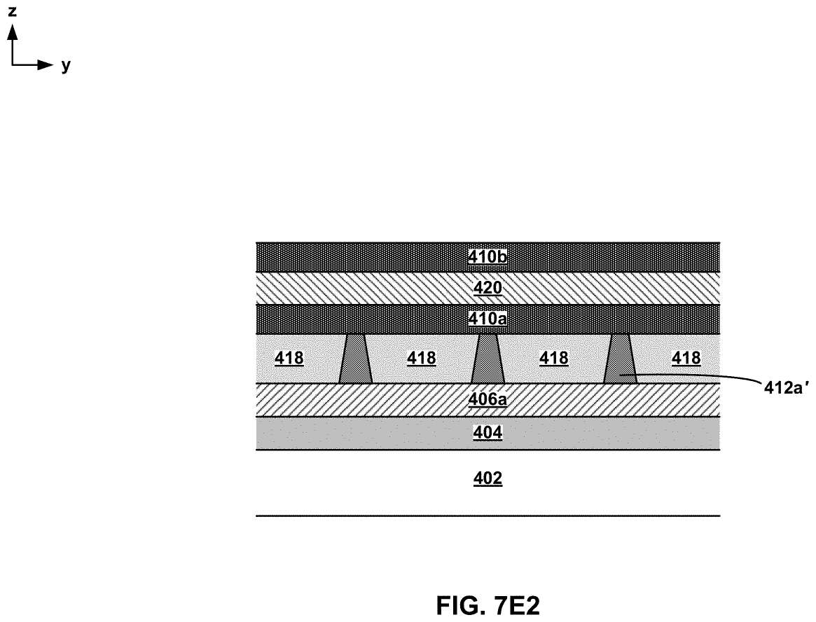

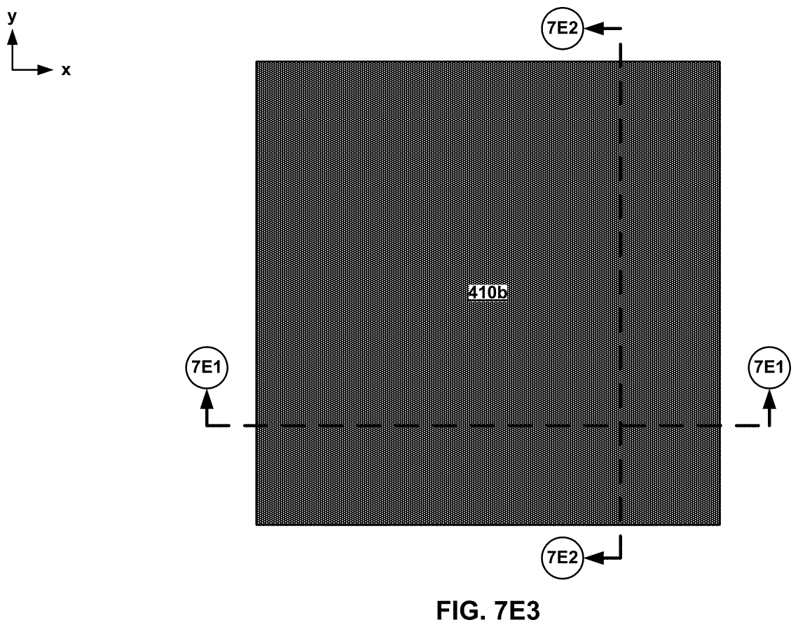

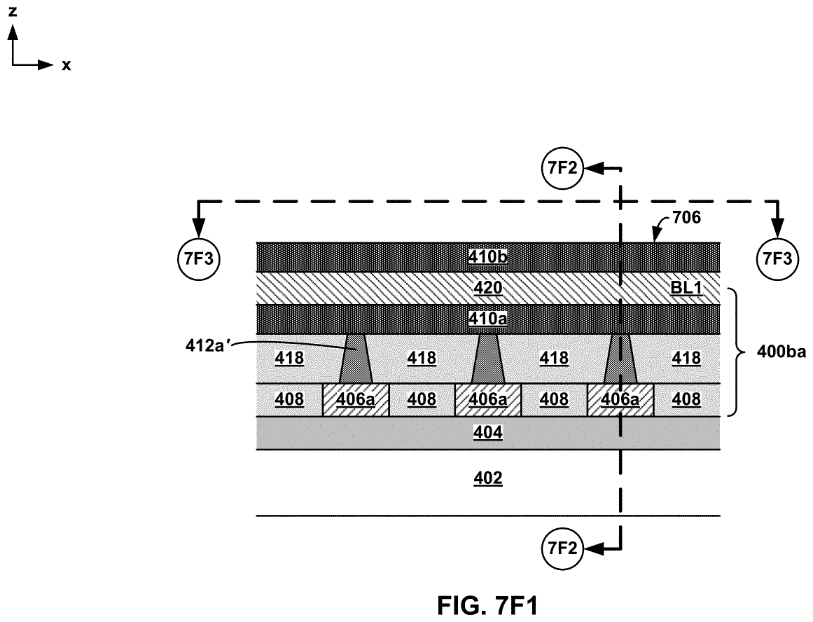

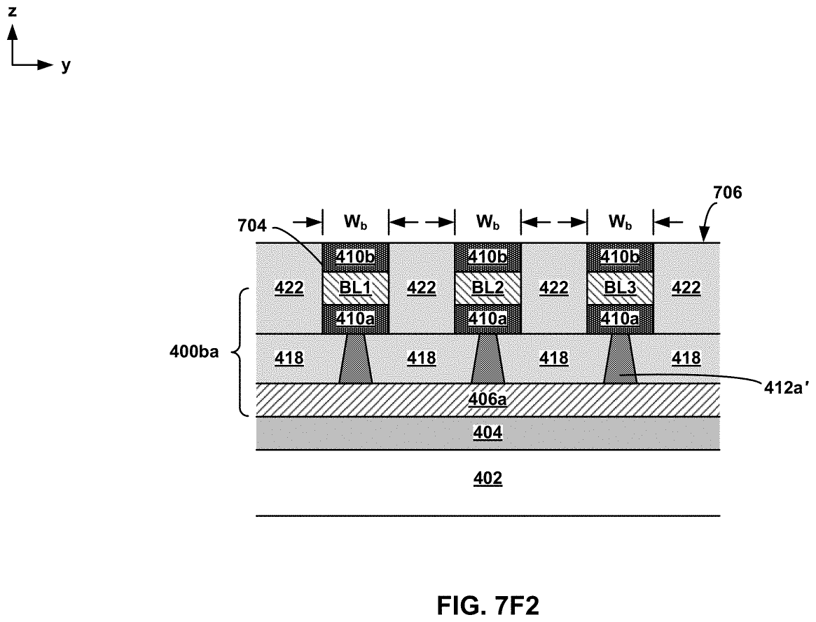

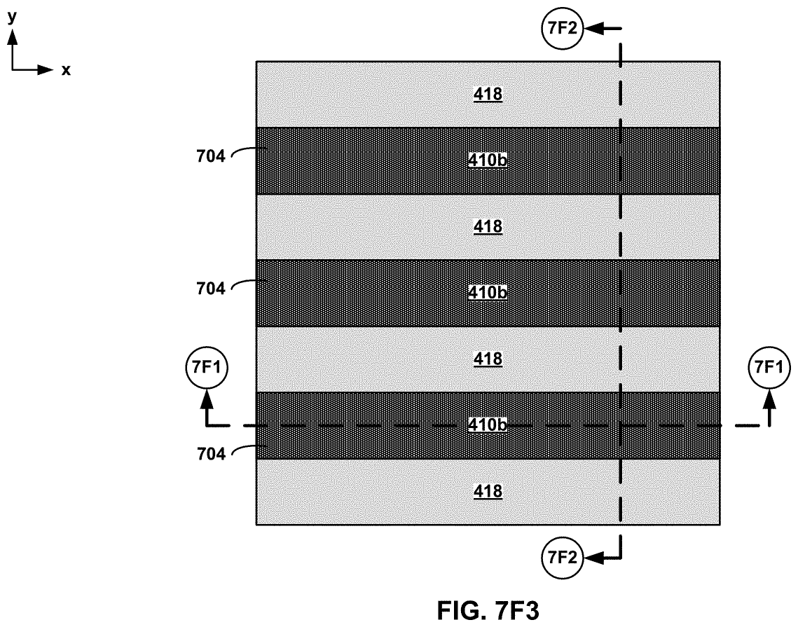

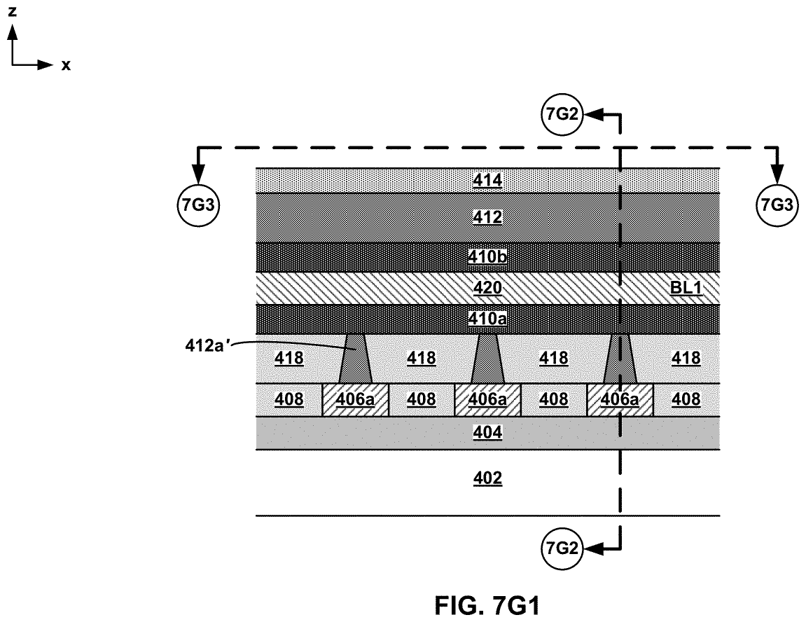

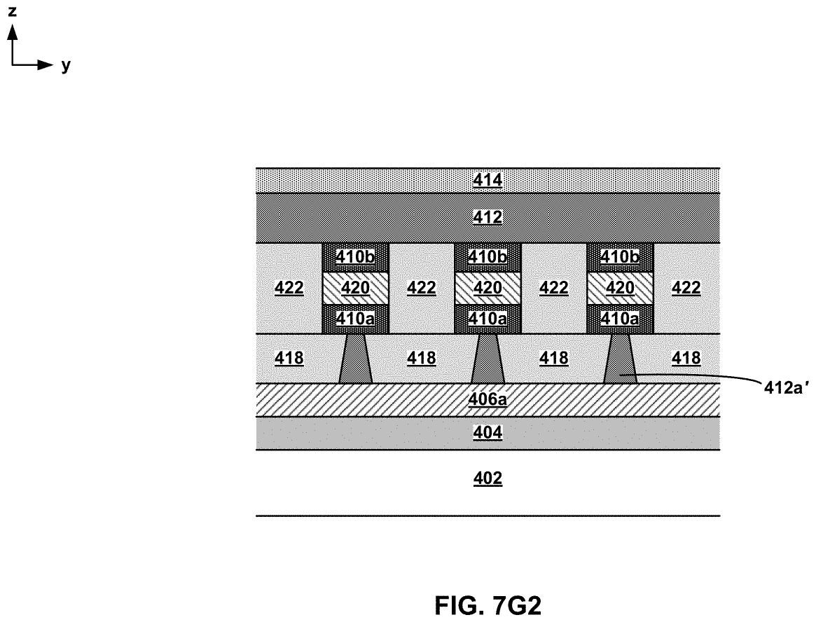

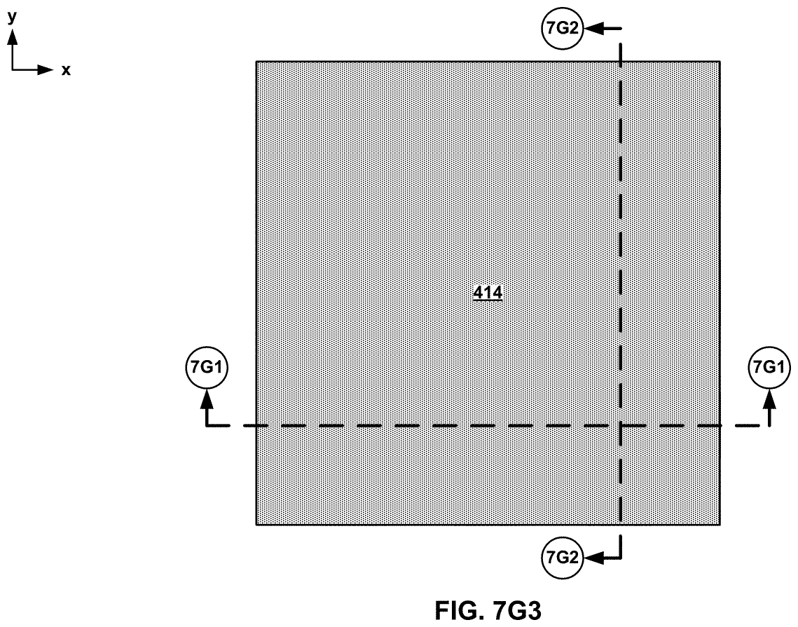

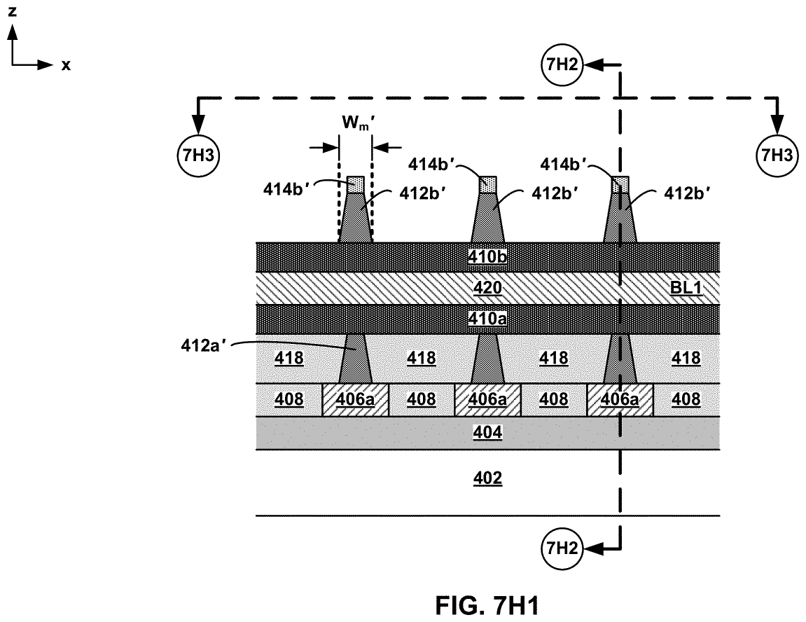

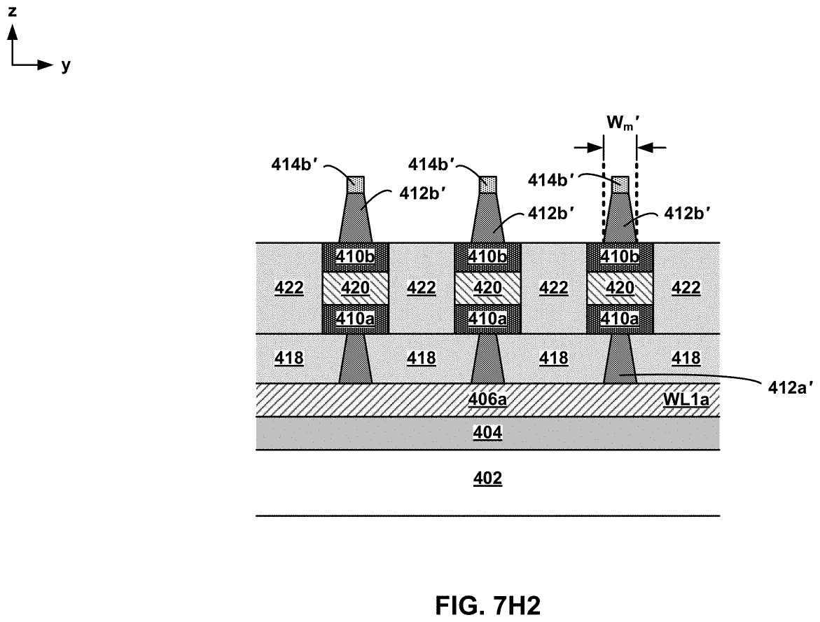

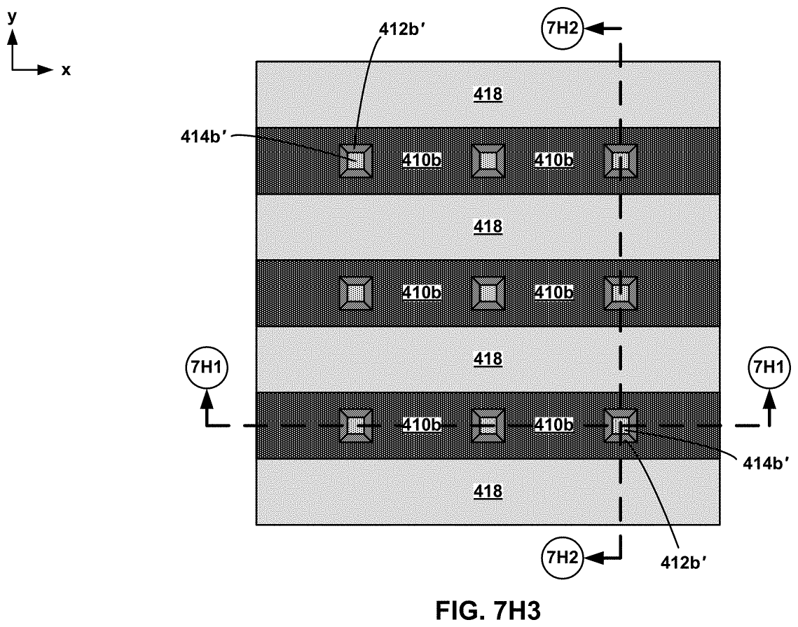

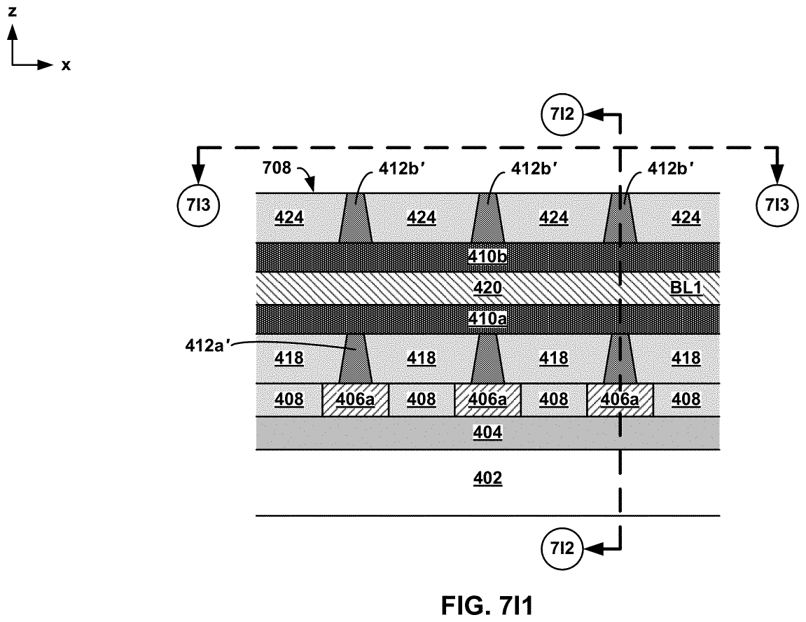

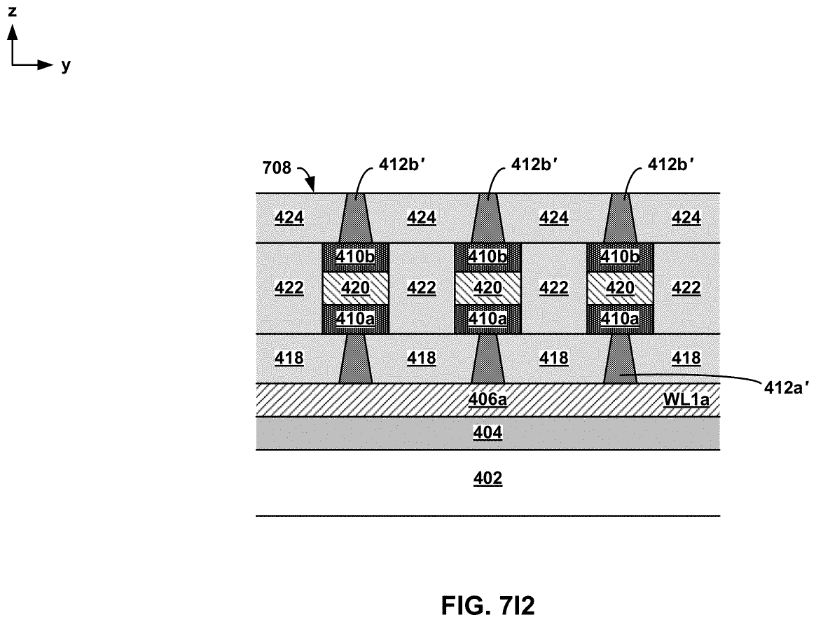

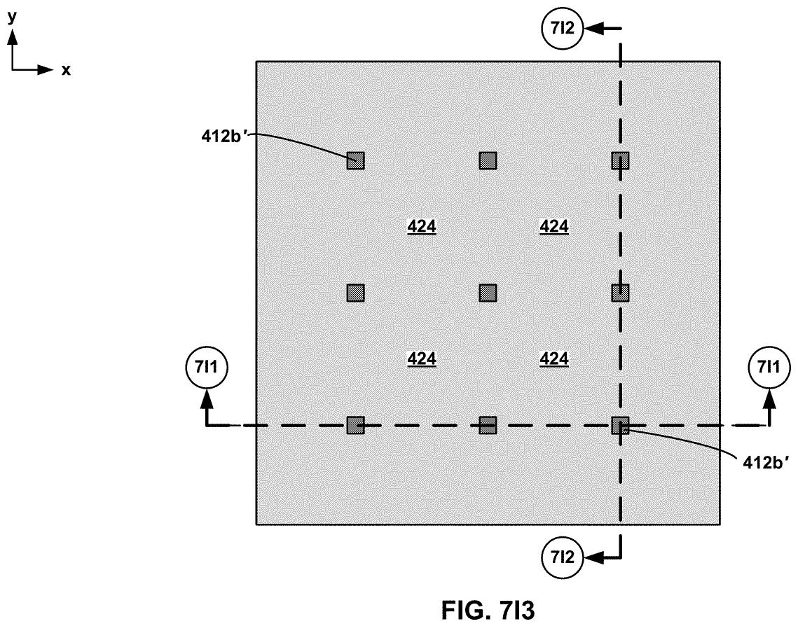

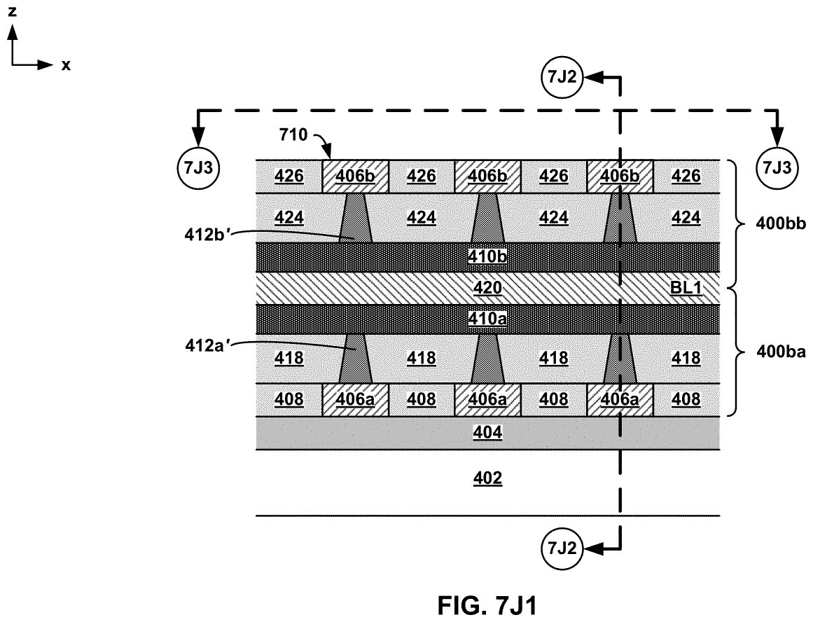

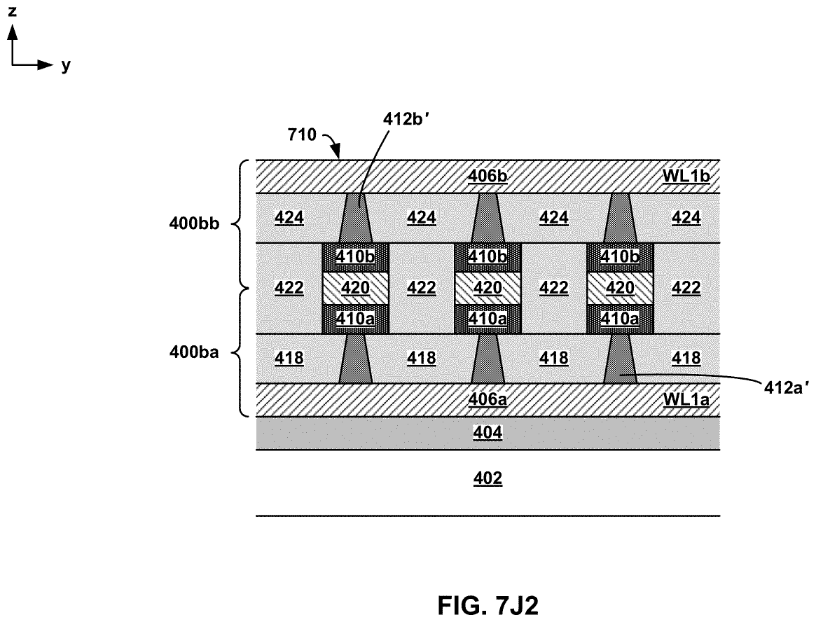

Referring now to FIGS. 7A1-7J3, another example method of forming a cross-point memory array is described. In particular, FIGS. 7A1-7J3 illustrate an example method of forming a cross-point memory array, such as cross-point memory array 400b of FIGS. 6A-6B. With reference to FIGS. 7A1-7A2, substrate 402 is shown as having already undergone several processing steps. Substrate 402 may be any suitable substrate such as a silicon, germanium, silicon-germanium, undoped, doped, bulk, silicon-on-insulator (SOI) or other substrate with or without additional circuitry. For example, substrate 402 may include one or more n-well or p-well regions (not shown). Isolation layer 404 is formed above substrate 402. In some embodiments, isolation layer 404 may be a layer of silicon dioxide, silicon nitride, silicon oxynitride or any other suitable insulating layer.

Following formation of isolation layer 404, conductive layer 406a is deposited over isolation layer 404. Conductive layer 406a may include any suitable conductive material such as copper or another appropriate metal, heavily doped semiconductor material, a conductive silicide, a conductive silicide-germanide, a conductive germanide, or the like deposited by any suitable method (e.g., CVD, PVD, etc.). In at least one embodiment, conductive layer 406a may be copper having a thickness between about 20 nm and about 100 nm. Other conductive layer materials and/or thicknesses may be used. In some embodiments, an adhesion layer (not shown), such as titanium nitride or other similar adhesion layer material, may be disposed between isolation layer 404 and conductive layer 406a.

Conductive layer 406a is then patterned and etched. For example, conductive layer 406a may be patterned and etched using conventional lithography techniques, with a soft or hard mask, and wet or dry etch processing. In at least one embodiment, conductive layer 406a is patterned and etched to form substantially parallel, substantially co-planar word lines WL1a, WL2a, WL3a. Word lines WL1a, WL2a, WL3a have a width W_{W}. Example widths W_{W} for word lines WL1a, WL2a, WL3a and/or spacings between word lines WL1a, WL2a, WL3a range between about 10 nm and about 60 nm, although other conductor widths and/or spacings may be used.

After word lines WL1a, WL2a, WL3a have been formed, first dielectric material layer 408 is formed over substrate 402 to fill the voids between word lines WL1a, WL2a, WL3a. For example, approximately 50-300 nm of silicon dioxide (SiO₂) may be deposited on the substrate 402 and planarized using chemical mechanical polishing or an etchback process to form a planar surface 700. As depicted in FIGS. 7A1-7A2, first dielectric material layer 408 fills the gaps between word lines WL1a, WL2a, WL3a. Other dielectric materials such as silicon oxynitride, low K dielectrics, etc., and/or other dielectric material layer thicknesses may be used. Example low K dielectrics include carbon doped oxides, silicon carbon layers, or the like.

In other embodiments, word lines WL1a, WL2a, WL3a may be formed using a damascene process in which first dielectric material layer 408 is formed, patterned and etched to form etched trenches for word lines WL1a, WL2a, WL3a. The openings or voids then may be filled with conductive layer 406a. In such an embodiment, conductive layer 406a will line the bottom and sidewalls of each trench.

Following planarization, magnetic memory material layer 412 is deposited over planar surface 700. Magnetic memory material layer 412 may be deposited by any suitable method (e.g., CVD, PVD, etc.). In an embodiment, magnetic memory material layer 412 has a total thickness between about 15 nm and about 30 nm.

In an embodiment, magnetic material layer 412 includes a layer stack of multiple material layers. Table 1, above, provides an example magnetic material layer 412 layer stack (from bottom to top) having a bottom pinned layer PL, and Table 2, above, provides an example magnetic material layer 412 layer stack (from bottom to top) having a top pinned layer (PL).

In other embodiments, other materials, thicknesses, and numbers of layers may be used for magnetic material layer 412. In embodiments, one or more hard mask material layers may be deposited above the example layer stacks listed in Tables 1 and 2, above. In an embodiment, a first hard mask layer (e.g., TaN) having a thickness between about 20 nm and about 40 nm is deposited on the layer stack. In embodiments, first hard mask layer includes materials that may be etched using reactive ion etching (RIE) techniques.

Next, hard mask layer 414 is deposited over magnetic material layer 412, resulting in the structure shown in FIGS. 7B1-7B3. In an embodiment, hard mask layer 414 is a material that is very resistant to ion milling. In an embodiment, hard mask layer 414 is between about 20 nm and about 60 nm of DLC. Other hard mask materials and/or thicknesses may be used.

Hard mask layer 414 is patterned and etched, resulting in residual hard mask features 414a′, and magnetic material layer 412 is etched (e.g., by patterned ion milling) to form pillar-shaped magnetic material layer structures 412a′. For example, the milling may stop after etching into conductive layer 406a, resulting in the structure shown in FIGS. 7C1-7C3. In an embodiment, magnetic material layer structures 412a′ have a maximum width Wₘ′ that is narrower than a width W_{W} of word lines WL1a, WL2a, WL3a. In embodiments, width Wm′ may be between about 10 nm and about 40 nm, although other widths may be used.

Third dielectric material layer 418 is deposited over substrate 402, filling gaps between magnetic material layer structures 412a′. For example, about 60 nm to about 150 nm of silicon dioxide may be deposited and planarized using chemical mechanical polishing or an etch-back process to expose top surfaces of magnetic material layer structures 412a′ and form a planar surface 702, resulting in the structure illustrated in FIGS. 7D1-7D3. Other dielectric materials such as silicon nitride, silicon oxynitride, high K dielectrics, etc., and/or other dielectric material layer thicknesses may be used.

Following planarization, first selector material layer 410a is deposited over substrate 402. First selector material layer 410a may be one or more chalcogenide materials, such as SiTe, SiAsSe, GeAsSe, GeAsSeSi. or mixtures thereof. In other embodiments, first selector material layer 410a may be a VCB with HfOx doped with one or more of Cu, Ag, or similar metallic ions. First selector material layer 410a may be deposited by any suitable method (e.g., CVD, PVD, etc.). In an embodiment, first selector material layer 410a may be between about 4 nm and about 30 nm of SiTe. In some embodiments, spacer/buffer layers (e.g., TaN, TiN, W, carbon, carbon nitride) (not shown) may be deposited above and/or below first selector material layer 410a. In some embodiments, a capping layer (e.g., TaN) may be deposited on first selector material layer 410a, and then removed by chemical mechanical polishing prior to subsequent material deposition steps. Persons of ordinary skill in the art will understand that other selector materials, material thicknesses and/or other deposition techniques may be used.

Next, conductive layer 420 is deposited over first selector material layer 410a. Conductive layer 420 may include any suitable conductive material such as tungsten or another appropriate metal, heavily doped semiconductor material, a conductive silicide, a conductive silicide-germanide, a conductive germanide, or the like deposited by any suitable method (e.g., CVD, PVD, etc.). In at least one embodiment, conductive layer 420 may be tungsten having a thickness between about 10 nm and about 50 nm. Other conductive layer materials and/or thicknesses may be used. In some embodiments, an adhesion layer (not shown), such as titanium nitride or other similar adhesion layer material, may be disposed between first selector material layer 410a and conductive layer 420.

Second selector material layer 410a is deposited over conductive layer 420, resulting in the structure shown in FIGS. 7E1-7E3. Second selector material layer 410b may be one or more chalcogenide materials, such as SiTe, SiAsSe, GeAsSe, GeAsSeSi or mixtures thereof. In other embodiments, second selector material layer 410b may be a VCB type, where HfOx is doped with one or more of Cu, Ag, or similar ion. Second selector material layer 410b may be deposited by any suitable method (e.g., CVD, PVD, etc.). In an embodiment, second selector material layer 410b may be between about 4 nm and about 30 nm of SiTe. In some embodiments, spacer/buffer layers (e.g., TaN, TiN, W, carbon, carbon nitride) (not shown) may be deposited above and/or below second selector material layer 410b. In some embodiments, a capping layer (e.g., TaN) may be deposited on second selector material layer 410b, and then removed by chemical mechanical polishing prior to subsequent material deposition steps. Persons of ordinary skill in the art will understand that other selector materials, material thicknesses and/or other deposition techniques may be used.

Second selector material layer 410b, conductive layer 420 and first selector material layer 410a are then patterned and etched. For example, second selector material layer 410b, conductive layer 420 and first selector material layer 410a may be patterned and etched using conventional lithography techniques, with a soft or hard mask, and wet or dry etch processing. In at least one embodiment, second selector material layer 410b, conductive layer 420 and first selector material layer 410a are patterned and etched to form substantially parallel, substantially co-planar rows 704 including bit lines BL1, BL2, BL3. Bit lines BL1, BL2, BL3 have a width W_{B}. Example widths W_{B} for rows 704 and bit lines BL1, BL2, BL3 and/or spacings between bit lines BL1, BL2, BL3 range between about 10 nm and about 60 nm, although other conductor widths and/or spacings may be used.

After bit lines BL1, BL2, BL3 have been formed, fourth dielectric material layer 422 is formed over substrate 402 to fill the voids between bit lines BL1, BL2, BL3. For example, approximately 300-700 nm of silicon dioxide may be deposited on the substrate 402 and planarized using chemical mechanical polishing or an etchback process to form a planar surface 706, resulting in the structure shown in FIGS. 7F1-7F3. Fourth dielectric material layer 422 fills the gaps between rows 704, and completes first memory level 400ba. Other dielectric materials such as silicon oxynitride, low K dielectrics, etc., and/or other dielectric material layer thicknesses may be used.

Following planarization, magnetic memory material layer 412 is deposited over planar surface 706. Magnetic memory material layer 412 may be deposited by any suitable method (e.g., CVD, PVD, etc.). In an embodiment, magnetic memory material layer 412 has a total thickness between about 15 nm and about 30 nm.

In an embodiment, magnetic material layer 412 includes a layer stack of multiple material layers. Table 1, above, provides an example magnetic material layer 412 layer stack (from bottom to top) having a bottom pinned layer PL, and Table 2, above, provides an example magnetic material layer 412 layer stack (from bottom to top) having a top pinned layer (PL).

In other embodiments, other materials, thicknesses, and numbers of layers may be used for magnetic material layer 412. In embodiments, one or more hard mask material layers may be deposited above the example layer stacks listed in Tables 1 and 2, above. In an embodiment, a first hard mask layer (e.g., TaN) having a thickness between about 20 nm and about 40 nm is deposited on the layer stack. In embodiments, first hard mask layer includes materials that may be etched using reactive ion etching (RIE) techniques.

Next, hard mask layer 414 is deposited over magnetic material layer 412, resulting in the structure shown in FIGS. 7B1-7B3. In an embodiment, hard mask layer 414 is a material that is very resistant to ion milling. In an embodiment, hard mask layer 414 is between about 20 nm and about 60 nm of DLC. Other hard mask materials and/or thicknesses may be used.

Hard mask layer 414 is patterned and etched, resulting in residual hard mask features 414b′, and magnetic material layer 412 is etched (e.g., by patterned ion milling) to form pillar-shaped magnetic material layer structures 412b′. For example, the milling may stop after etching into second selector material layer 410b, resulting in the structure shown in FIGS. 7H1-7H3. In an embodiment, magnetic material layer structures 412b′ have a maximum width Wₘ′ that is narrower than a width W_{w} of word lines WL1a, WL2a, WL3a. In embodiments, width Wm′ may be between about 10 nm and about 50 nm, although other widths may be used.

Sixth dielectric material layer 424 is deposited over substrate 402, filling gaps between magnetic material layer structures 412b′. For example, about 10 nm to about 80 nm of silicon dioxide may be deposited and planarized using chemical mechanical polishing or an etch-back process to expose top surfaces of magnetic material layer structures 412b′ and form a planar surface 708, resulting in the structure illustrated in FIGS. 711-713. Other dielectric materials such as silicon nitride, silicon oxynitride, high K dielectrics, etc., and/or other dielectric material layer thicknesses may be used.

Following planarization, conductive layer 406b is deposited over planar surface 708. Conductive layer 406b may include any suitable conductive material such as copper or another appropriate metal, heavily doped semiconductor material, a conductive silicide, a conductive silicide-germanide, a conductive germanide, or the like deposited by any suitable method (e.g., CVD, PVD, etc.). In at least one embodiment, conductive layer 406b may be copper having a thickness between about 10 nm and about 100 nm. Other conductive layer materials and/or thicknesses may be used. In some embodiments, an adhesion layer (not shown), such as titanium nitride or other similar adhesion layer material, may be disposed between sixth dielectric material layer 424 and top surfaces of magnetic material layer structures 412b′ and conductive layer 406b.

Conductive layer 406b is then patterned and etched. For example, conductive layer 406b may be patterned and etched using conventional lithography techniques, with a soft or hard mask, and wet or dry etch processing. In at least one embodiment, conductive layer 406b is patterned and etched to form substantially parallel, substantially co-planar word lines WL1b, WL2b, WL3b, each having a width W_{W}. Example widths W_{W} for word lines WL1b, WL2b, WL3b and/or spacings between word lines WL1b, WL2b, WL3b range between about 10 nm and about 60 nm, although other conductor widths and/or spacings may be used.

After word lines WL1b, WL2b, WL3b have been formed, seventh dielectric material layer 426 is formed over substrate 402 to fill the voids between word lines WL1b, WL2b, WL3b. For example, approximately 80-300 nm of silicon dioxide (SiO₂) may be deposited on the substrate 402 and planarized using chemical mechanical polishing or an etchback process to form a planar surface 710. As depicted in FIGS. 7J1-7J3, seventh dielectric material layer 426 fills the gaps between word lines WL1b, WL2b, WL3b, and completes first memory level 400bb. Other dielectric materials such as silicon oxynitride, low K dielectrics, etc., and/or other dielectric material layer thicknesses may be used. Example low K dielectrics include carbon doped oxides, silicon carbon layers, or the like.

In other embodiments, word lines WL1b, WL2b, WL3b may be formed using a damascene process in which seventh dielectric material layer 426 is formed, patterned and etched to form etched trenches for word lines WL1b, WL2b, WL3b. The openings or voids then may be filled with conductive layer 406b. In such an embodiment, conductive layer 406b will line the bottom and sidewalls of each trench.

Thus, the example steps described above may be used to form a cross-point memory array, such as cross-point memory array 400b of FIGS. 6A-6B. The regions of first selector material layer 410a above magnetic material layer structures 412a′ constitute selector elements S₁₁ₐ′, S₁₂ₐ′, . . . , S₃₃ₐ′, and magnetic material layer structures 412a′ constitute magnetic memory element M₁₁ₐ′, M₁₂ₐ′, . . . , M₃₃ₐ′. (See FIGS. 6A-6B). Likewise, the regions of second selector material layer 410b below magnetic material layer structures 412b′ constitute selector elements S_{11b}′, S_{12b}′, . . . , S_{33b}′, and magnetic material layer structures 412b′ constitute magnetic memory element M_{11b}′, M_{12b}′, . . . , M_{33b}′. (See FIGS. 6A-6B).

As described above in connection with FIGS. 6A-6B, in an embodiment magnetic memory elements M₁₁ₐ′, M₁₂ₐ′, . . . , M₃₃ₐ′ of first memory level 400ba each have a first magnetic writing polarity, and magnetic memory elements M_{11b}′, M_{12b}′, . . . , M_{33b}′ of second memory level 400bb each have a second magnetic writing polarity. In an embodiment, the first polarity is the same as the second polarity. In another embodiment, the second polarity is opposite the first polarity. In the process steps described above and depicted in FIGS. 7A1-5J3, the magnetic writing polarities of magnetic memory elements M₁₁ₐ′, M₁₂ₐ′, . . . , M₃₃ₐ′ of first memory level 400ba and magnetic memory elements M_{11b}′, M_{12b}′, . . . , M_{33b}′ of second memory level 400bb may be set based on the deposition order (e.g., bottom-pinned as described above and depicted in Table 1, or top-pinned as described above and depicted in Table 2) of material layers of magnetic material layer 412 for first memory level 400ba and second memory level 400bb.

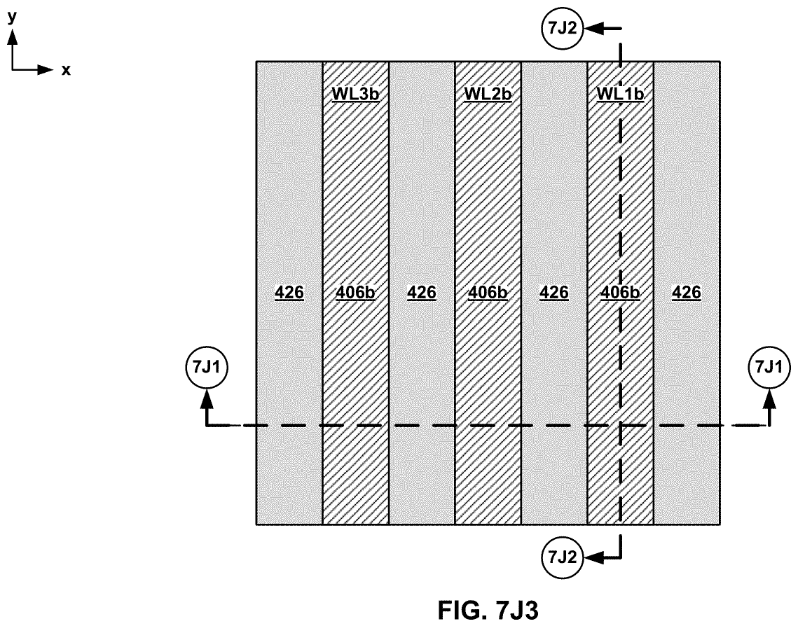

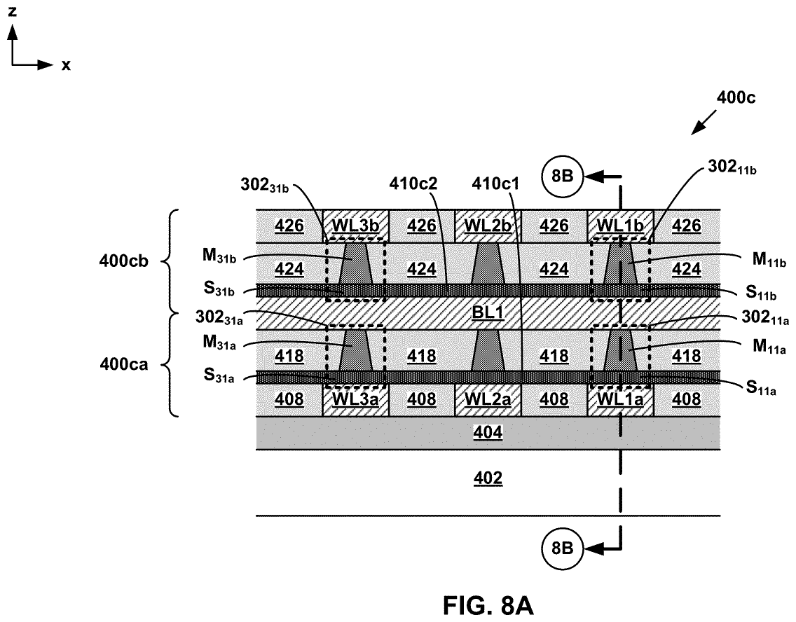

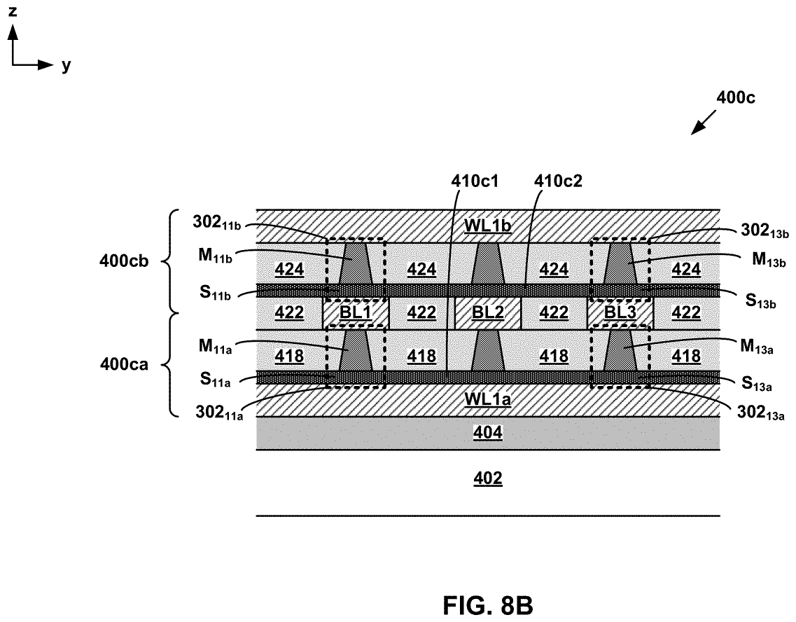

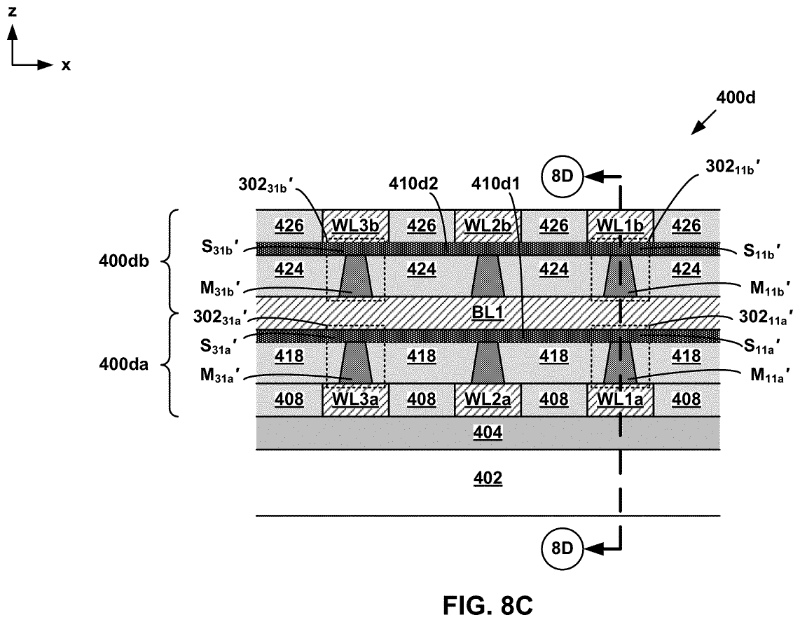

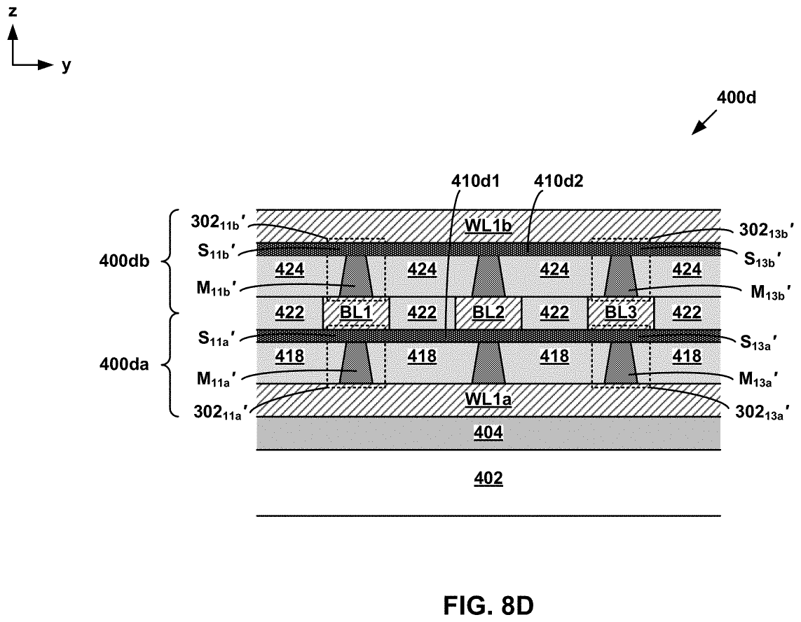

FIGS. 8A-8B depict various views of an embodiment of a cross-point memory array 400c that includes memory cells that each include a magnetic memory element coupled in series with a selector element. The physical structure depicted in FIGS. 8A-8B may include one implementation of cross-point memory array 300 of FIGS. 3A-3B.

Cross-point memory array 400c includes a first memory level 400ca (corresponding to first memory level 300a of FIG. 3A), and a second memory level 400cb (corresponding to second memory level 300b of FIG. 3B) positioned above first memory level 400ca. Cross-point memory array 400c may include more than two memory levels. Cross-point memory array 400c is an example of an implementation of memory array 160 in FIG. 1E.

Cross-point memory array 400c is similar to cross-point memory array 400a of FIGS. 4A-4B, but includes selector material layers 410c1 and 410c2 that are planes of selector material. That is, selector material layers 410c1 and 410c2 are deposited but not patterned at the memory cell level (as in cross-point memory array 400a of FIGS. 4A-4B) or at the line level (as in cross-point memory array 400b of FIGS. 6A-6B). The example processing steps of FIGS. 5A1-5H3, described above, may be used to form cross-point memory array 400c of FIGS. 8A-8B, except that the encapsulation step and second dielectric material 416a deposition step (FIGS. 5C1-5C3) are omitted, and the anisotropic etch step to remove lateral portions of second dielectric material 416a and first selector material layer 410a (FIGS. 5D1-5D3) also is omitted.

In the embodiment of FIGS. 8A-8B, the regions of selector material layer 410c1 below magnetic memory elements M₁₁ₐ, M₁₂ₐ, . . . , M₃₃ₐ constitute selector elements S₁₁ₐ, S₁₂ₐ, . . . , S₃₃ₐ, respectively, and the regions of selector material layer 410c2 below magnetic memory elements M_{11b}, M_{12b}, . . . , M_{33b} selector elements S_{11b}, S_{12b}, . . . , S_{33b}, respectively.

FIGS. 8C-8D depict various views of an embodiment of a cross-point memory array 400d that includes memory cells that each include a magnetic memory element coupled in series with a selector element. The physical structure depicted in FIGS. 8C-8D may include one implementation of cross-point memory array 300 of FIGS. 3A-3B.

Cross-point memory array 400d includes a first memory level 400da (corresponding to first memory level 300a of FIG. 3A), and a second memory level 400db (corresponding to second memory level 300b of FIG. 3B) positioned above first memory level 400da. Cross-point memory array 400d may include more than two memory levels. Cross-point memory array 400d is an example of an implementation of memory array 160 in FIG. 1E.

Cross-point memory array 400d is similar to cross-point memory array 400a of FIGS. 4A-4B, but includes selector material layers 410d1 and 410d2 that are planes of selector material. That is, selector material layers 410d1 and 410d2 are deposited but not patterned at the memory cell level (as in cross-point memory array 400a of FIGS. 4A-4B) or at the line level (as in cross-point memory array 400b of FIGS. 6A-6B). The example processing steps of FIGS. 7A1-7J3, described above, may be used to form cross-point memory array 400d of FIGS. 8C-8D, except that selector material layers 410d1 and 410d2 are not patterned and etched.

In the embodiment of FIGS. 8C-8D, the regions of selector material layer 410d1 above magnetic memory elements M₁₁ₐ′, M₁₂ₐ′, . . . , M₃₃ₐ′ constitute selector elements S₁₁ₐ′, S₁₂ₐ′, . . . , S₃₃ₐ′, respectively, and the regions of selector material layer 410d2 above magnetic memory elements M_{11b}′, M_{12b}′, . . . , M_{33b}′ selector elements S_{11b}′, S_{12b}′, . . . , S_{33b}′, respectively.

One embodiment of the disclosed technology includes a memory array that includes a first memory level including a plane of first selector material, and a plurality of first memory cells each including a corresponding first magnetic memory element coupled in series with a corresponding first selector element. Each first selector element includes a region of the plane of first selector material.

One embodiment of the disclosed technology includes a method of forming a memory array. The method includes forming a plurality of memory cells by forming a plurality of magnetic memory elements above a substrate, forming a selector material layer above the plurality of magnetic memory elements, and etching the selector material layer to form a plurality of rows of selector material. The plurality of memory cells each include a corresponding magnetic memory element coupled in series with one of the rows of selector material.

One embodiment of the disclosed technology includes a method of forming a memory array. The method includes forming a plurality of first memory cells by forming a selector material layer above a substrate, forming a magnetic memory layer above the selector material layer, milling the magnetic memory layer to form a plurality of magnetic memory elements, forming a dielectric material over the plurality of magnetic memory elements and the selector material layer, and anisotropically etching the dielectric material and selector material layer to form a plurality of selector elements. Each selector element is disposed below a corresponding magnetic memory element.

For purposes of this document, a first layer may be over or above a second layer if zero, one, or more intervening layers are between the first layer and the second layer.

For purposes of this document, it should be noted that the dimensions of the various features depicted in the figures may not necessarily be drawn to scale.

For purposes of this document, reference in the specification to “an embodiment,” “one embodiment,” “some embodiments,” or “another embodiment” may be used to describe different embodiments and do not necessarily refer to the same embodiment.

For purposes of this document, a connection may be a direct connection or an indirect connection (e.g., via another part). In some cases, when an element is referred to as being connected or coupled to another element, the element may be directly connected to the other element or indirectly connected to the other element via intervening elements. When an element is referred to as being directly connected to another element, then there are no intervening elements between the element and the other element.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A memory array comprising:
a first memory level comprising:
a plane of first selector material; and
a plurality of first memory cells each comprising a corresponding first magnetic memory element coupled in series with a corresponding first selector element, wherein each first selector element comprises a region of the plane of first selector material.

2. The memory array of claim 1, wherein each first selector element comprises one or more of a threshold selector device, a conductive bridge threshold selector device, an ovonic threshold switch, and a Metal Insulator Transition of a Phase Transition Material type threshold selector device.

3. The memory array of claim 1, wherein the plane of first selector material comprises one or more of SiTe, CTe, BTe, AlTe, SiAsTe, GeAsSe, GeAsSeSi, VO₂, and NbO₂.

4. The memory array of claim 1, wherein the plane of first VCB selector material comprises HfOₓ doped with one or more of Cu, Ag, or similar metallic ion.

5. The memory array of claim 1, wherein each first memory cell is vertically-oriented.

6. The memory array of claim 1, further comprising a plurality of word lines and a plurality of bit lines, wherein each first memory cell is disposed between one of the plurality of word lines and one of the plurality of bit lines.

7. The memory array of claim 1, comprising a cross-point memory array.

8. The memory array of claim 1, further comprising a second memory level disposed above the first memory level, the second memory level comprising:
a plane of second selector material; and
a plurality of second memory cells each comprising a corresponding second magnetic memory element coupled in series with a corresponding second selector element, wherein each second selector element comprises a region of the plane of second selector material.

9. The memory array of claim 8, wherein each first magnetic memory element comprises a first magnetic writing polarity, and each second magnetic memory element comprises a second magnetic writing polarity the same as the first magnetic writing polarity.

10. The memory array of claim 8, wherein each first magnetic memory element comprises a first magnetic writing polarity, and each second magnetic memory element comprises a second magnetic writing polarity opposite the first polarity.

11. The memory array of claim 8, further comprising a plurality of word lines and a plurality of bit lines, wherein the first memory level and the second memory level share one of the plurality of word lines and the plurality of bit lines.

12. A method of forming a memory array, the method comprising:
forming a plurality of memory cells by:
forming a plurality of magnetic memory elements above a substrate;
forming a selector material layer above the plurality of magnetic memory elements; and
etching the selector material layer to form a plurality of rows of selector material,
wherein the plurality of memory cells each comprise a corresponding magnetic memory element coupled in series with one of the rows of selector material.

13. The method of claim 12, wherein the selector material comprises one or more of SiTe, CTe, BTe, AlTe, SiAsTe, GeAsSe, GeAsSeSi, VO₂, and NbO₂

14. The method of claim 12, wherein the selector material comprises a VCB type of selector with HfOx doped with one or more of Cu, Ag, or similar ions.

15. The method of claim 12, wherein each memory cell is vertically-oriented.

16. The method of claim 12, further comprising forming a plurality of word lines and a plurality of bit lines, wherein each memory cell is disposed between one of the plurality of word lines and one of the plurality of bit lines.

17. The method of claim 12, wherein the memory array comprises a cross-point memory array.

18. A method of forming a memory array, the method comprising:
forming a plurality of first memory cells by:
forming a selector material layer above a substrate;
forming a magnetic memory layer above the selector material layer;
milling the magnetic memory layer to form a plurality of magnetic memory elements;
forming a dielectric material over the plurality of magnetic memory elements and the selector material layer; and
anisotropically etching the dielectric material and selector material layer to form a plurality of selector elements, each selector element disposed below a corresponding magnetic memory element.

19. The method of claim 18, wherein each selector element comprises one or more of a threshold selector device, a conductive bridge threshold selector device, an ovonic threshold switch, and a Metal Insulator Transition of a Phase Transition Material type threshold selector device.

20. The method of claim 18, further comprising forming a plurality of second memory cells above the plurality of first memory cells.
